(19) United States
(12) Patent Application Publication
(10) Pub. No.: US 2015/0255607 A1
(43) Pub. Date: Sep. 10, 2015

(54) SEMICONDUCTOR DEVICE HAVING STRESSOR AND METHOD OF FABRICATING THE SAME

(71) Applicant: Samsung Electronics Co., Ltd., Suwon-si (KR)

(72) Inventors: Sun-Me Lim, Yongin-si (KR); Ju-Hyeong Ham, Suwon-si (KR)

(21) Appl. No.: 14/491,029

(22) Filed: Sep. 19, 2014

(30) Foreign Application Priority Data
Mar. 10, 2014 (KR) 10-2014-0027974

(51) Int. Cl. H01L 29/78; H01L 29/08; H01L 29/06; H01L 29/161; H01L 29/165

(52) U.S. Cl. CPC H01L 29/7848; H01L 29/7835; H01L 29/161; H01L 29/165; H01L 29/0653; H01L 29/0847

(57) ABSTRACT

A semiconductor device includes a stressor. A device isolation layer is formed on a substrate to define an active region. A gate electrode is formed on the active region. A trench is formed in the active region adjacent to the gate electrode and has first and second sidewalls. A stressor is formed within the trench. The first sidewall of the trench is near the gate electrode and relatively far away from the device isolation layer. The second sidewall of the trench is near the device isolation layer and relatively far away from the gate electrode. The second sidewall of the trench has a step shape.

### CROSS-REFERENCE TO RELATED APPLICATION

This U.S. non-provisional application claims priority under 35 U.S.C. §119 to Korean Patent Application No. 10-2014-0027974, filed on Mar. 10, 2014 in the Korean Intellectual Property Office (KIPO), the contents of which are herein incorporated by reference in their entirety.

### BACKGROUND

1. Field

The present inventive concepts provide a semiconductor device having a stressor and a method of fabricating the same.

2. Description of Related Art

Various methods for improving electrical properties of semiconductor devices using stressors are being researched.

### SUMMARY

Some embodiments of the present inventive concepts provide a semiconductor device including a stressor having a desired shape.

Some embodiments of the present inventive concepts provide a method of fabricating a semiconductor device having a stressor.

According to an aspect of the present inventive concepts, a semiconductor device includes a device isolation layer configured to define an active region on a substrate, a gate electrode on the active region, and a trench formed in the active region adjacent to the gate electrode and having first and second sidewalls. A stressor is within the trench. The first sidewall of the trench is nearer to the gate electrode than to the device isolation layer. The second sidewall of the trench is nearer to the device isolation layer than to the gate electrode. The second sidewall of the trench has a step shape.

In some embodiments, the second sidewall of the trench may include an upper sidewall, a middle sidewall, and a lower sidewall. The middle sidewall may be inclined at a different slope than the upper sidewall and the lower sidewall. The upper sidewall may be formed at a higher level than the lower sidewall. The middle sidewall may be formed between the upper sidewall and the lower sidewall.

In some embodiments, the middle sidewall may be substantially parallel to a bottom of the trench.

In some embodiments, the middle sidewall may be formed at a higher level than a lower end of the stressor.

In some embodiments, a crossing angle between the bottom of the trench and the lower sidewall may be an obtuse angle. A crossing angle between the lower sidewall and the middle sidewall may be an obtuse angle. A crossing angle between the middle sidewall and the upper sidewall may be an obtuse angle.

In some embodiments, the upper sidewall may be formed at a lower level than an upper end of the device isolation layer.

In some embodiments, the upper sidewall may be formed at a lower level than an upper end of the active region.

In some embodiments, the first sidewall of the trench may have a sigma (Σ) shape or a notch shape.

In some embodiments, the first sidewall of the trench may include an upper sidewall being in contact with a top surface of the active region, and a lower sidewall formed between a bottom of the trench and the upper sidewall. The upper sidewall and the lower sidewall may have a convergent interface.

In some embodiments, a crossing angle between the top surface of the active region and the upper sidewall may be an acute angle. A crossing angle between the bottom of the trench and the lower sidewall may be an obtuse angle.

In some embodiments, the stressor may include a first semiconductor layer, a second semiconductor layer on the first semiconductor layer, and a third semiconductor layer on the second semiconductor layer. The first semiconductor layer and the second semiconductor layer may include silicon germanium (SiGe), and germanium (Ge) may be contained in the second semiconductor layer at a higher content than in the first semiconductor layer.

In some embodiments, the third semiconductor layer may contain silicon (Si) or silicon germanium, and germanium may be contained in the third semiconductor layer at a lower content than in the second semiconductor layer.

According to another aspect of the present inventive concepts, a semiconductor device includes a device isolation layer configured to define an active region on a substrate, a gate electrode covering at least one side surface of the active region, and a trench formed in the active region adjacent to the gate electrode and having first and second sidewalls. A stressor is within the trench. The first sidewall of the trench is nearer to the gate electrode than the device isolation layer. The second sidewall of the trench is nearer to the device isolation layer than to the gate electrode. The second sidewall of the trench has a step shape.

In some embodiments, a lower end of the gate electrode may be formed at a lower level than an upper end of the active region.

In some embodiments, the second sidewall of the trench may include an upper sidewall, a middle sidewall, and a lower sidewall. The middle sidewall may be inclined at a different slope from the upper sidewall and the lower sidewall.

According to another aspect of the present inventive concepts, a semiconductor device includes a device isolation layer configured to define an active region on a substrate, a gate electrode on the active region, and a trench formed in the active region adjacent to the gate electrode. The trench includes a first sidewall near the gate electrode, a second sidewall contacting the device isolation layer and having a step shape, and a bottom. The first sidewall is spaced apart from the second sidewall by the bottom. A stressor is within the trench.

In some embodiments, the second sidewall of the trench includes an upper sidewall, a middle sidewall, and a lower sidewall. The middle sidewall is inclined at a different slope than the upper sidewall and the lower sidewall, the upper sidewall is formed at a higher level than the lower sidewall, and the middle sidewall is formed between the upper sidewall and the lower sidewall.

In some embodiments, the middle sidewall is substantially parallel to a bottom of the trench.

In some embodiments, a crossing angle between the bottom of the trench and the lower sidewall is an obtuse angle, a crossing angle between the lower sidewall and the middle sidewall is an obtuse angle, and a crossing angle between the middle sidewall and the upper sidewall is an obtuse angle.

In some embodiments, the stressor includes a first semiconductor layer, a second semiconductor layer on the first semiconductor layer, and a third semiconductor layer on the second semiconductor layer. The first semiconductor layer and the second semiconductor layer include silicon germanium (SiGe), and germanium (Ge) is contained in the second semiconductor layer at a higher content than in the first semiconductor layer.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIG. 1 is a cross-sectional view of a semiconductor device according to example embodiments of the present inventive concepts.

FIG. 2 is a layout diagram of a semiconductor device according to example embodiments of the present inventive concepts.

FIGS. 3 through 6 are cross-sectional views of a semiconductor device according to example embodiments of the present inventive concepts.

FIG. 7 is a layout diagram of a semiconductor device according to example embodiments of the present inventive concepts.

FIGS. 8 through 10 are cross-sectional views taken along lines and IV-IV′ of FIG. 7, illustrating a semiconductor device according to example embodiments of the present inventive concepts.

FIGS. 11 through 22 are cross-sectional views taken along line I-I′ of FIG. 2 illustrating a method of fabricating a semiconductor device according to example embodiments of the present inventive concepts.

FIGS. 23 and 24 are cross-sectional views taken along line I-I′ of FIG. 2 illustrating a method of fabricating a semiconductor device according to embodiments of the inventive concepts.

FIG. 25 is a cross-sectional view taken along line I-I′ of FIG. 2 illustrating a method of fabricating a semiconductor device according to example embodiments of the present inventive concepts.

FIGS. 26 and 27 are cross-sectional views taken along line I-I′ of FIG. 2, illustrating a method of fabricating a semiconductor device according to example embodiments of the inventive concepts.

FIGS. 28 through 42 are cross-sectional views taken along lines III-III′ and IV-IV′ of FIG. 7 illustrating a method of fabricating a semiconductor device according to example embodiments of the present inventive concepts.

FIGS. 43 and 44 are a perspective view and a system block diagram, respectively, of an electronic device according to example embodiments of the present inventive concepts.

FIG. 45 is a schematic block diagram of an electronic system including at least one of the semiconductor devices according to example embodiments of the present inventive concepts.

### DETAILED DESCRIPTION OF THE EMBODIMENTS

Various example embodiments will now be described more fully hereinafter with reference to the accompanying drawings, in which some embodiments of the present inventive concepts are shown. The present inventive concepts may, however, be embodied in different forms and should not be construed as limited to the embodiments set forth herein.

The terminology used herein is for the purpose of describing particular example embodiments only and is not intended to be limiting of the present inventive concepts. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

Spatially relative terms, such as “beneath”, “below”, “lower”, “above”, “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation(s) depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (for example, rotated 90 degrees or at other orientations) and the spatially relative descriptors used herein interpreted accordingly.

Example embodiments are described herein with reference to plan and cross-section illustrations that are schematic illustrations of idealized example embodiments (and intermediate structures). As such, variations from the shapes of the illustrations as a result, for example, of manufacturing techniques and/or tolerances, are to be expected. Thus, example embodiments of the present inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Relative terms, such as “front side” and “back side”, may be used herein for ease of description to describe the present inventive concepts. Accordingly, a front side or back side does not necessarily indicate a specific direction, location, or component, but can be used interchangeably. For example, a front side could be interpreted as a back side, and a back side could be interpreted as a front side. Accordingly, a front side could be termed a first side, and a back side could be termed a second side. Conversely, a back side could be termed a first side, and a front side could be termed a second side.

In the present specification, a term “near” indicates that any one of at least two components having symmetrical concepts is disposed nearer to another specific component than the others thereof. For instance, when a first end is near a first side, it may be inferred that the first end is nearer to the first side than a second end or that the first end is nearer to the first side than a second side.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

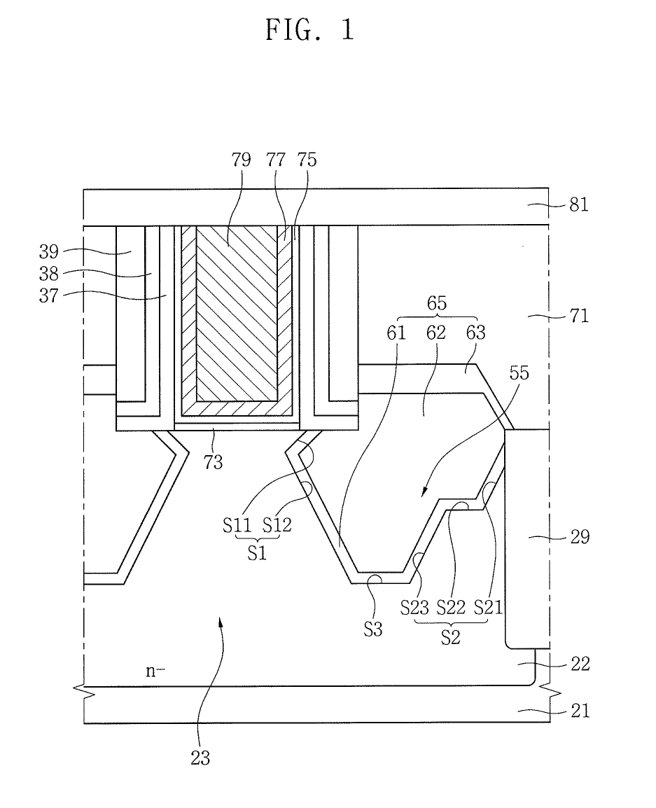

FIG. 1 is a cross-sectional view of a semiconductor device according to example embodiments of the present inventive concepts.

Referring to FIG. 1, a well 22, an active region 23, a device isolation layer 29, a trench 55, an embedded stressor 65, a first gate dielectric layer 73, a second gate dielectric layer 75, a lower gate electrode 77, an upper gate electrode 79, first spacers 37, second spacers 38, third spacers 39, an interlayer insulating layer 71, and an upper insulating layer 81 may be formed on a substrate 21. The embedded stressor 65 may include a first semiconductor layer 61, a second semiconductor layer 62, and a third semiconductor layer 63.

The trench 55 may include a first sidewall S1, a second sidewall S2, and a bottom S3. The active region 23 may be exposed to the first sidewall S1, the second sidewall S2, and the bottom S3 of the trench 55. That is, the first sidewall S1, the second sidewall S2 and the bottom S3 are formed along sidewalls of the active region 23. The second sidewall S2 may be spaced apart from the first sidewall S1. The first sidewall S1 and the second sidewall S2 are coupled by bottom S3. The first sidewall S1 may be near the upper gate electrode 79 and relatively far away from the device isolation layer 29. The second sidewall S2 may be near the device isolation layer 29 and relatively far away from the upper gate electrode 79. That is, the first sidewall S1 is nearer to the upper gate electrode 79 than the second sidewall S2 and the second sidewall S2 is nearer to the device isolation layer 29 than the first sidewall S1.

The first sidewall S1 may exhibit a sigma (Σ) shape or a notch shape. The first sidewall S1 may include a first upper sidewall S11 and a first lower sidewall S12. The first upper sidewall S11 may be in contact with a top surface of the active region 23. A crossing angle between the top surface of the active region 23 and the first upper sidewall S11 may form an acute angle. That is, the first upper sidewall S11 interfaces with the top surface of the active region 23 at an acute angle. The first lower sidewall S12 may be formed under the first upper sidewall S11. The first lower sidewall S12 may be in contact with the first upper sidewall S11 and the bottom S3. A crossing angle between the bottom S3 and the first lower sidewall S12 may form an obtuse angle. That is, the first lower sidewall S12 interfaces with the bottom S3 at an obtuse angle. The first upper sidewall S11 and the first lower sidewall S12 may have a convergent interface. A crossing angle between the first upper sidewall S11 and the first lower sidewall S12 may form an obtuse angle. That is, the first upper sidewall S11 interfaces with the first lower sidewall S12 at an obtuse angle.

The second sidewall S2 may exhibit a step shape. The second sidewall S2 may include a second upper sidewall S21, a second middle sidewall S22, and a second lower sidewall S23. The second upper sidewall S21 may be formed at a higher level than the second lower sidewall S23. The second middle sidewall S22 may be formed between the second upper sidewall S21 and the second lower sidewall S23. The second lower sidewall S23 may be spaced apart from the first lower sidewall S12 and may be in contact with the bottom S3. That is, the bottom S3 couples the first lower sidewall S12 to second lower sidewall S23. A crossing angle between the second lower sidewall S23 and the bottom S3 may form an obtuse angle. That is, the second lower sidewall S23 interfaces with the bottom S3 at an obtuse angle. The second middle sidewall S22 may be formed at a higher level than the bottom S3. The second middle sidewall S22 may be in contact with the second lower sidewall S23 and the second upper sidewall S21. A crossing angle between the second middle sidewall S22 and the second lower sidewall S23 may form an obtuse angle. That is, the second middle sidewall S22 interfaces with the second lower sidewall S23 at an obtuse angle.

The second middle sidewall S22 may be inclined at a different slope from the second upper sidewall S21 and the second lower sidewall S23. The second middle sidewall S22 may be substantially parallel to the bottom S3. The second upper sidewall S21 may be spaced apart from the second lower sidewall S23 and may be in contact with the second middle sidewall S22. A crossing angle between the second upper sidewall S21 and the second middle sidewall S22 may form an obtuse angle. That is, the second upper sidewall S21 interfaces with the second middle sidewall S22 at an obtuse angle. One end of the second upper sidewall S21 may be in contact with the device isolation layer 29. The second upper sidewall S21 may be formed at a higher level than the second lower sidewall S23. The second upper sidewall S21 may be formed at a lower level than an upper end, or a top surface, of the device isolation layer 29. The second upper sidewall S21 may be formed at a lower level than an upper end, or a top surface, of the active region 23.

According to the example embodiments of the present inventive concepts, due to a configuration, for example, the step shape, of the second sidewall S2, the embedded stressor 65 may be formed to densely fill the inside of the trench 55. An upper end of the embedded stressor 65 may protrude at a higher level than the upper end, or the top surface, of the active region 23. The embedded stressor 65 fills the trench so that no vacant space is formed in the trench near the device isolation layer 29.

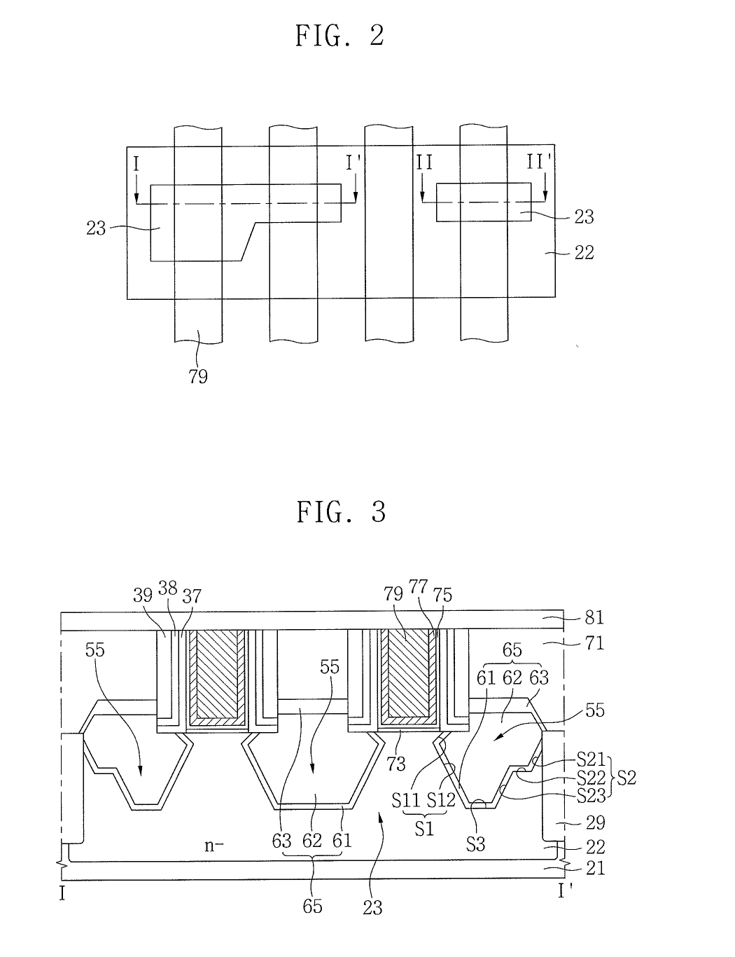

FIG. 2 is a layout of a semiconductor device according to example embodiments of the present inventive concepts.

Referring to FIG. 2, a plurality of active regions 23 and a plurality of upper gate electrodes 79 may be formed on the well 22. The gate electrodes 79 may extend in parallel to one another. The gate electrodes 79 may cross the active regions 23. Each of the active regions 23 may exhibit various sizes and shapes.

FIG. 3 is a cross-sectional view taken along line I-I′ of FIG. 2 illustrating a semiconductor device according to example embodiments of the present inventive concepts. FIG. 1 may be a detailed enlarged view of a portion of FIG. 3.

Referring to FIGS. 2 and 3, the well 22, the active region 23, the device isolation layer 29, the trenches 55, the embedded stressors 65, the first gate dielectric layers 73, the second gate dielectric layers 75, the lower gate electrodes 77, the upper gate electrodes 79, the first spacers 37, the second spacers 38, the third spacers 39, the interlayer insulating layer 71, and the upper insulating layer 81 may be formed on the substrate 21. Each of the embedded stressors 65 may include the first semiconductor layer 61, the second semiconductor layer 62, and the third semiconductor layer 63.

At least one of the trenches 55 may include the first sidewall S1, the second sidewall S2, and the bottom S3. The embedded stressors 65 may fill the trenches 55. The embedded stressors 65 may be in direct contact with the first sidewalls S1, the second sidewalls S2, and the bottoms S3 of the trenches 55.

The embedded stressors 65 may fill trenches 55 between adjacent upper gate electrodes 79 extending over a single active region 23. The embedded stressors between adjacent upper electrodes 79 may include first and second sidewalls and a bottom coupling the first and second sidewalls. The first sidewall and second sidewalls may exhibit a sigma (Σ) shape or a notch shape, similar to the first sidewall S1 described above.

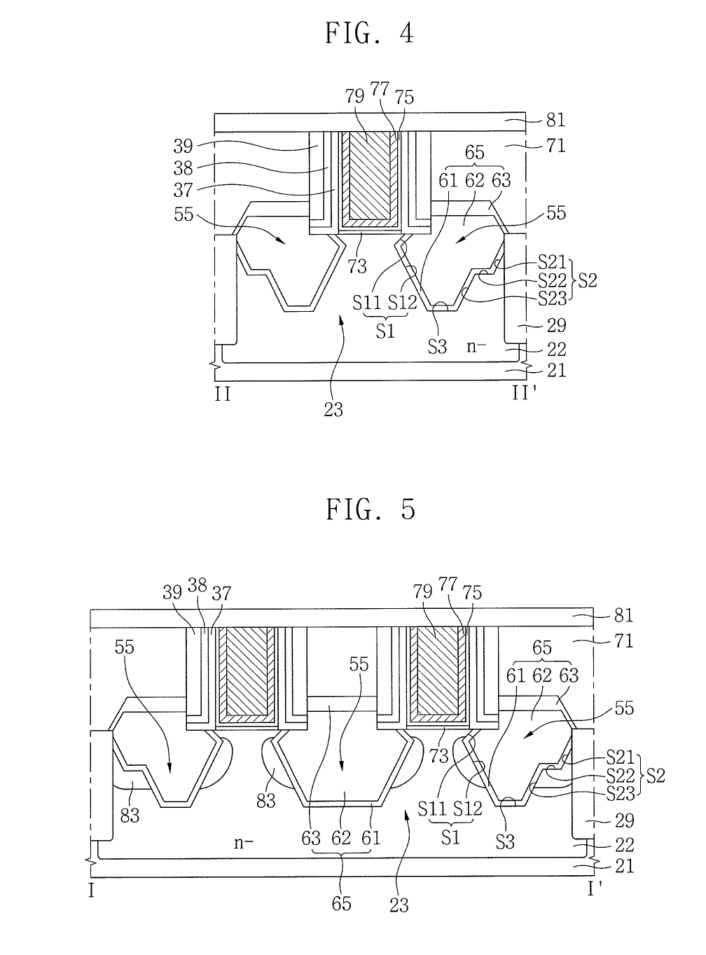

FIG. 4 is a cross-sectional view taken along line II-II′ of FIG. 2 illustrating a semiconductor device according to example embodiments of the present inventive concepts.

Referring to FIGS. 2 and 4, the well 22, the active region 23, the device isolation layer 29, the trenches 55, the embedded stressors 65, the first gate dielectric layer 73, the second gate dielectric layer 75, the lower gate electrode 77, the upper gate electrode 79, the first spacers 37, the second spacers 38, the third spacers 39, the interlayer insulating layer 71, and the upper insulating layer 81 may be formed on the substrate 21. Each of the embedded stressors 65 may include the first semiconductor layer 61, the second semiconductor layer 62, and the third semiconductor layer 63.

At least one of the trenches 55 may include the first sidewall S1, the second sidewall S2, and the bottom S3. The embedded stressors 65 may fill the trenches 55. The embedded stressors 65 may be in direct contact with the first sidewalls S1, the second sidewalls S2, and the bottoms S3 of the trenches 55.

FIG. 5 is a cross-sectional view taken along line I-I′ of FIG. 2 illustrating a semiconductor device according to example embodiments of the present inventive concepts.

Referring to FIGS. 2 and 5, a halo 83 may be formed. The halo 83 may contain impurities of the same conductivity type as the active region 23. For example, the halo 83 and the active region 23 may contain phosphorus (P), arsenic (As), or a combination thereof. The halo 83 may be formed in the active region 23 adjacent to the embedded stressors 65. The halo 83 may be formed at a lower level than an upper end, or top surface, of the active region 23. The active region 23 may be retained between the halo 83 and the first gate dielectric layer 73. The halo 83 may be formed around portions of the first upper sidewall S11, portions of the first lower sidewall S12, portions of the second upper sidewalls S21, portions of second middle sidewall S22 and portions of the second lower sidewalls S23.

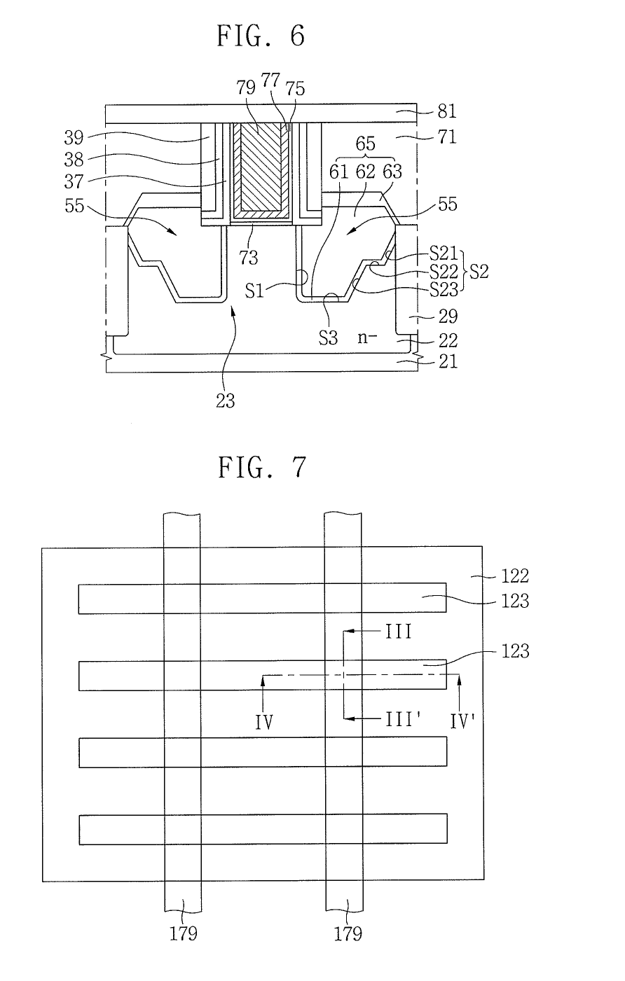

FIG. 6 is a cross-sectional view of a semiconductor device according to example embodiments of the present inventive concepts.

Referring to FIG. 6, the well 22, the active region 23, the device isolation layer 29, the trenches 55, the embedded stressors 65, the first gate dielectric layer 73, the second gate dielectric layer 75, the lower gate electrode 77, the upper gate electrode 79, the first spacers 37, the second spacers 38, the third spacers 39, the interlayer insulating layer 71, and the upper insulating layer 81 may be formed on the substrate 21. Each of the embedded stressors 65 may include the first semiconductor layer 61, the second semiconductor layer 62, and the third semiconductor layer 63.

Each of the trenches 55 may include the first sidewall S1, the second sidewall S2, and the bottom S3. The first sidewall S1 may be near the upper gate electrode 79 and relatively far away from the device isolation layer 29. The first sidewall S1 may exhibit a vertical configuration with respect to the surface of the substrate 21. The first sidewall S1 may be a substantially straight line. The first sidewall S1 may be interpreted as being vertical to the bottom S3. That is, the first sidewall may be substantially perpendicular to the bottom S3.

In some embodiments, the first sidewall S1 may have various shapes, such as an inclined shape, a bent shape, a curved shape, or a combination thereof.

FIG. 7 is a layout diagram of a semiconductor device according to example embodiments of the present inventive concepts.

Referring to FIG. 7, a plurality of active regions 123 and a plurality of upper gate electrodes 179 may be formed on an N-well 122. The gate electrodes 179 may extend in parallel to one another. The gate electrodes 179 may cross the active regions 123. The active regions 123 may be parallel to one another. The gate electrodes 179 may be substantially perpendicular to the active regions 123. Each of the active regions 123 may have various shapes, for example, a fin shape or a wire shape. For example, each of the active regions 123 may include fin-shaped single-crystalline silicon having a relatively long major axis.

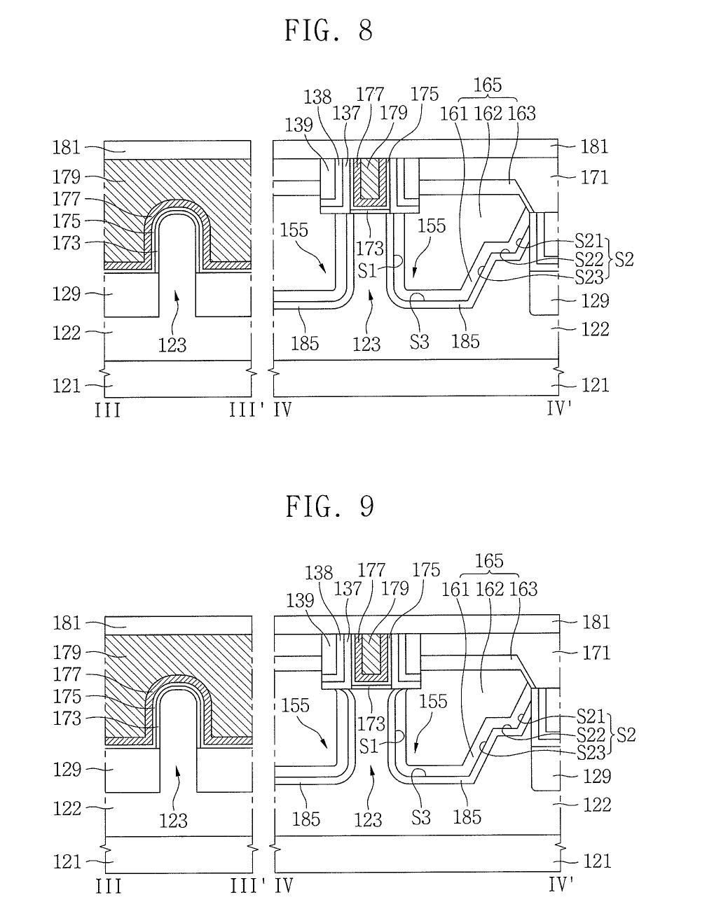

FIGS. 8 through 10 are cross-sectional views taken along lines and IV-IV′ of FIG. 7 illustrating a semiconductor device according to example embodiments of the present inventive concepts.

Referring to FIGS. 7 and 8, the N-well 122, the active region 123, a device isolation layer 129, a trench 155, an embedded stressor 165, a lightly-doped drain (LDD) 185, a first gate dielectric layer 173, a second gate dielectric layer 175, a lower gate electrode 177, an upper gate electrode 179, first spacers 137, second spacers 138, third spacers 139, an interlayer insulating layer 171, and an upper insulating layer 181 may be formed on a substrate 121. The embedded stressor 165 may contain a first semiconductor layer 161, a second semiconductor layer 162, and a third semiconductor layer 163. The lower gate electrode 177 and the upper gate electrode 179 may cover a top surface and side surfaces of the active region 123. A lower end of the upper gate electrode 179 may be formed at a lower level than the top surface of the active region 123 and at a higher level than a bottom surface of the active region 123.

The trench 155 may contain a first sidewall S1, a second sidewall S2, and a bottom S3. The active region 123 may be exposed to the first sidewall S1, the second sidewall S2, and the bottom S3 of the trench 155. That is, the first sidewall S1, the second sidewall S2 and the bottom S3 are formed along sidewalls of the active region 123. The second sidewall S2 may be spaced apart from the first sidewall S1. The first sidewall S1 and the second sidewall S2 are coupled by the bottom S3. The first sidewall S1 may be near the upper gate electrode 179 and relatively far away from the device isolation layer 129. The second sidewall S2 may be near the device isolation layer 129 and relatively far away from the upper gate electrode 179. That is, the first sidewall S1 is nearer to the upper gate electrode 179 than the second sidewall S2 and the second sidewall S2 is nearer to the device isolation layer 129 than the first sidewall S1. The first sidewall S1 may be vertically formed with respect to the surface of the substrate 121. The first sidewall S1 may be interpreted as being vertical with respect to the bottom S3. The first sidewall S1 may be a substantially straight line and may be substantially perpendicular with respect to the substrate 121 and the bottom S3.

The second sidewall S2 may exhibit a step shape. The second sidewall S2 may include a second upper sidewall S21, a second middle sidewall S22, and a second lower sidewall S23. The second upper sidewall S21 may be formed at a higher level than the second lower sidewall S23. The second middle sidewall S22 may be formed between the second upper sidewall S21 and the second lower sidewall S23. The second lower sidewall S23 may be spaced apart from the first lower sidewall S12 and may be in contact with the bottom S3. That is, the bottom S3 couples the first lower sidewall S12 to second lower sidewall S23. A crossing angle between the second lower sidewall S23 and the bottom S3 may form an obtuse angle. That is, the second lower sidewall S23 interfaces with the bottom S3 at an obtuse angle. The second middle sidewall S22 may be formed at a higher level than the bottom S3. The second middle sidewall S22 may be in contact with the second lower sidewall S23 and the second upper sidewall S21. A crossing angle between the second middle sidewall S22 and the second lower sidewall S23 may form an obtuse angle. That is, the first upper sidewall S11 interfaces with the first lower sidewall S12 at an obtuse angle.

The second middle sidewall S22 may be substantially parallel to the bottom S3. The second upper sidewall S21 may be spaced apart from the second lower sidewall S23 and may be in contact with the second middle sidewall S22. A crossing angle between the second upper sidewall S21 and the second middle sidewall S22 may form an obtuse angle. That is, the second upper sidewall S21 interfaces with the second middle sidewall S22 at an obtuse angle. The second upper sidewall S21 may be formed at a higher level than the second lower sidewall S23. The second upper sidewall S21 may be formed at a lower level than an upper end, or top surface, of the active region 123.

Referring to FIGS. 7 and 9, the first sidewall S1 may exhibit various shapes. For example, an upper end of the first sidewall S1 may have a bent shape.

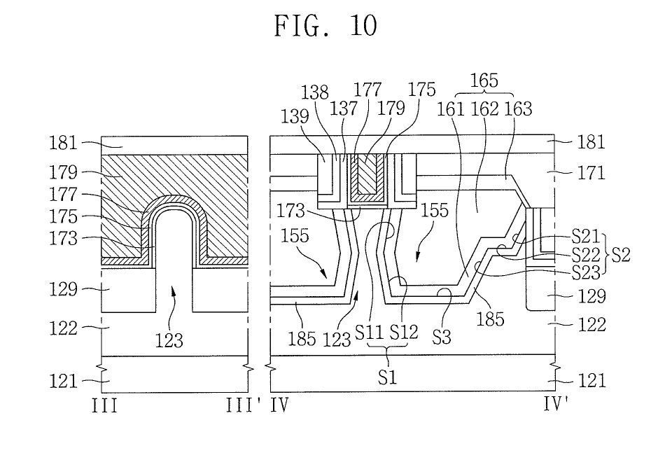

Referring to FIGS. 7 and 10, the first sidewall S1 may exhibit various shapes. For example, the first sidewall S1 may exhibit a sigma (Σ) shape or a notch shape. The first sidewall S1 may include a first upper sidewall S11 and a first lower sidewall S12. The first upper sidewall S11 may be in contact with the top surface of the active region 123. A crossing angle between the top surface of the active region 123 and the first upper sidewall S11 may form an acute angle. That is, the first upper sidewall S11 interfaces with the top surface of the active region 23 at an acute angle. The first lower sidewall S12 may be formed under the first upper sidewall S11. The first lower sidewall S12 may be in contact with the first upper sidewall S11 and the bottom S3. A crossing angle between the bottom S3 and the first lower sidewall S12 may form an obtuse angle. That is, the first lower sidewall S12 interfaces with the bottom S3 at an obtuse angle. The first upper sidewall S11 and the first lower sidewall S12 may have a convergent interface. A crossing angle between the first upper sidewall S11 and the first lower sidewall S12 may form an obtuse angle. That is, the first upper sidewall S11 interfaces with the first lower sidewall S12 at an obtuse angle.

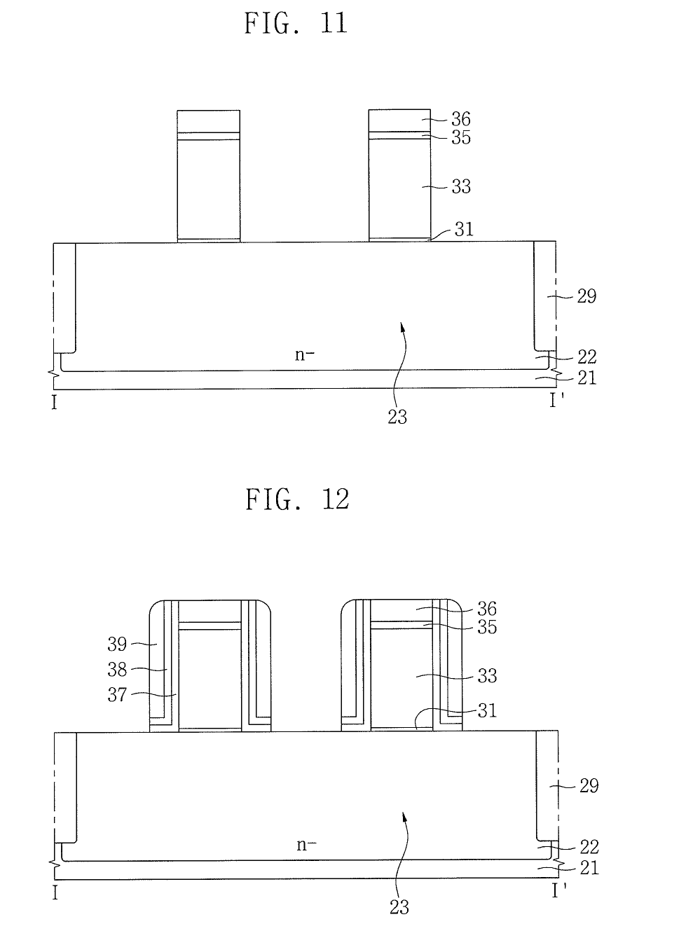

FIGS. 11 through 22 are cross-sectional views taken along line I-I′ of FIG. 2 illustrating a method of fabricating a semiconductor device according to example embodiments of the present inventive concepts.

Referring to FIGS. 2 and 11, a well 22, an active region 23, a device isolation layer 29, preliminary gate dielectric layers 31, preliminary gate electrodes 33, first mask patterns 35, and second mask patterns 36 may be formed on a substrate 21. The substrate 21 may be a single-crystalline semiconductor substrate, for example, a silicon wafer or a silicon-on-insulator (SOI) wafer. The substrate 21 may include impurities of a first conductivity type, for example, P-type. The well 22 may contain impurities of a second conductivity type different from the first conductivity type, for example, N-type.

Hereinafter, an embodiment in which the first conductivity type is a P-type and the second conductivity type is an N-type will be described; however, the present inventive concepts are not limited thereto. For example, the substrate 21 may include single-crystalline silicon containing P-type impurities, and the well 22 may include single-crystalline silicon containing N-type impurities. The substrate 21 may include, for example, boron (B), and the well 22 may include, for example, arsenic (As), phosphorus (P), or a combination thereof.

In some embodiments, the first conductivity type may be an N-type, and the second conductivity type may be P-type.

The active region 23 may be defined in the well 22 by the device isolation layer 29. The active region 23 may include, for example, single-crystalline silicon containing N-type impurities. For example, the active region 23 may include, for example, arsenic (As), phosphorus (P), or a combination thereof. The device isolation layer 29 may be formed using a shallow trench isolation (STI) technique. The device isolation layer 29 may include an insulating material, for example, silicon oxide, silicon nitride, silicon oxynitride, or a combination thereof. A plurality of active regions 23 may be formed in the well 22 spaced apart from one another. The active region 23 may be formed in the well 22 to have various shapes.

The preliminary gate dielectric layer 31 may be interposed between the active region 23 and the preliminary gate electrode 33. The preliminary gate dielectric layer 31 may include an insulating material, for example, silicon oxide, silicon nitride, silicon oxynitride, or a combination thereof. For example, the preliminary gate dielectric layer 31 may include silicon oxide. The preliminary gate electrode 33 may be formed to cross the active region 23. The preliminary gate electrode 33 may cross the active region 23 and the device isolation layer 29. The preliminary gate electrode 33 may include, for example, polysilicon (poly-Si). In some embodiments, the preliminary gate electrode 33 may include, for example, an insulating layer.

The first mask pattern 35 may be formed on the preliminary gate electrode 33. The first mask pattern 35 may include a material having an etch selectivity with respect to the preliminary gate electrode 33. The second mask pattern 36 may be formed on the first mask pattern 35. The second mask pattern 36 may include a material having an etch selectivity with respect to the first mask pattern 35. For example, the first mask pattern 35 may include, for example, silicon oxide, and the second mask pattern 36 may include, for example, silicon nitride or poly-Si. One of the first mask pattern 35 and the second mask pattern 36 may be omitted.

Side surfaces of the second mask pattern 36, the first mask pattern 35, the preliminary gate electrode 33, and the preliminary gate dielectric layer 31 may be substantially vertically aligned. The second mask pattern 36, the first mask pattern 35, the preliminary gate electrode 33, and the preliminary gate dielectric layer 31 may be referred to as a preliminary gate pattern 31, 33, 35, and 36. The preliminary gate pattern 31, 33, 35, and 36 may cross the active region 23. A plurality of preliminary gate patterns 31, 33, 35, and 36 may be formed on the active region 23 parallel to one another.

Referring to FIGS. 2 and 12, first spacers 37, second spacers 38, and third spacers 39 may be formed on sidewalls of the preliminary gate electrodes 33, the preliminary gate dielectric layer 31, the first mask pattern 35 and the second mask pattern 36. The formation of the first spacers 37, the second spacers 38, and the third spacers 39 may include a plurality of thin layer forming processes and a plurality of anisotropic etching processes. The top surface of the active region 23 may be exposed outside the preliminary gate electrodes 33, the first spacers 37, the second spacers 38, and the third spacers 39. The second spacers 38 may be retained between the first spacers 37 and the third spacers 39. The first spacers 37 and the second spacers 38 may be retained between the preliminary gate electrode 33 and the third spacers 39.

Each of the first spacers 37, the second spacers 38, and the third spacers 39 may include an insulating material, for example, silicon oxide, silicon nitride, silicon oxynitride, or a combination thereof. The first spacers 37, the second spacers 38, and the third spacers 39 may include a material having an etch selectivity with respect to the preliminary gate electrode 33. For example, the first spacers 37 may include silicon nitride.

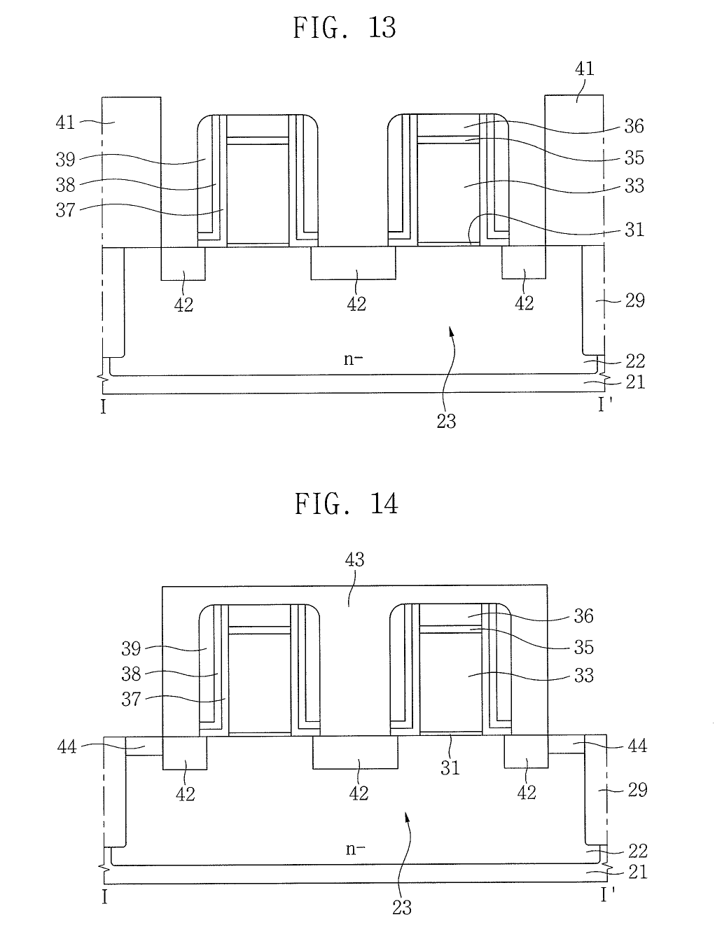

Referring to FIGS. 2 and 13, a third mask pattern 41 may be formed on the substrate 21. A high-speed etched region 42 may be formed in the active region 23 using the third mask pattern 41 as an ion implantation mask. The first spacers 37, the second spacers 38, the third spacers 39 and the second mask pattern 36 may be used as an ion implantation mask. An ion implantation process for forming the high-speed etched region 42 may be performed using various energy levels and various doses. The third mask pattern 41 may be removed to expose the high-speed etched region 42 and the active region 23.

The third mask pattern 41 may include, for example, a photoresist layer, a hard mask layer, or a combination thereof. The third mask pattern 41 may partially cover the device isolation layer 29 and the active region 23. The third mask pattern 41 may cover a portion of the active region 23, which may be near the device isolation layer 29 and relatively far away from the preliminary gate electrode 33. The high-speed etched region 42 may be formed in the active region 23 near the preliminary gate electrode 33. The active region 23 may remain without the ions implanted therein between the high-speed etched region 42 and the device isolation layer 29. That is, the third mask pattern 41 is formed on a portion of the active region 23 adjacent to the device isolation layer 29 and is spaced apart from the preliminary gate electrode 33.

Referring to FIGS. 2 and 14, a fourth mask pattern 43 may be formed on the substrate 21. A low-speed etched region 44 may be formed in the active region 23 using the fourth mask pattern 43 as an ion implantation mask. An ion implantation process for forming the low-speed etched region 44 may be performed using various energy levels and various doses. A sidewall of the fourth mask pattern 43 may be substantially vertically aligned with an outer sidewall of the high-speed etched region 42. The fourth mask pattern 43 may be removed to expose the high-speed etched region 42 and the low-speed etched region 44.

The fourth mask pattern 43 may include, for example, a photoresist layer, a hard mask layer, or a combination thereof. The fourth mask pattern 43 may partially cover the preliminary gate electrode 33 and the active region 23. The fourth mask pattern 43 may cover the active region 23, which may be near the preliminary gate electrode 33 and relatively far away from the device isolation layer 29. The fourth mask pattern 43 may cover the high-speed etched region 42. The fourth mask pattern 43 may expose the portion of the active region 23 between the high-speed etched region 42 and the device isolation layer 29. The low-speed etched region 44 may be formed in the active region 23, which may be near the device isolation layer 29 and relatively far away from the preliminary gate electrode 33. The low-speed etched region 44 may be formed in the active region 23 between the high-speed etched region 42 and the device isolation layer 29.

A lower end of the high-speed etched region 42 may be formed at a lower level than a lower end of the low-speed etched region 44. A lower end of the low-speed etched region 44 may be formed at a higher level than the lower end of the high-speed etched region 42. A first side surface of the low-speed etched region 44 may be in contact with a side surface of the high-speed etched region 42 and a second side surface of the low-speed etched region 44 may be in contact with the device isolation layer 29. Top surfaces of the active region 23, the high-speed etched region 42, and the low-speed etched region 44 may be substantially coplanar. The lower end of the high-speed etched region 42 may be formed at a higher level than a lower end of the device isolation layer 29.

The high-speed etched region 42 and the low-speed etched region 44 may include, for example, boron (B), boron fluoride (BF), phosphorus (P), arsenic (As), barium (Ba), germanium (Ge), silicon (Si), gallium (Ga), tin (Sn), antimony (Sb), carbon (C), nitrogen (N), or a combination thereof. The high-speed etched region 42 may include impurities at a higher dopant concentration than the active region 23. The low-speed etched region 44 may include impurities at a lower dopant concentration than the high-speed etched region 42.

The low-speed etched region 44 may include different impurities from the high-speed etched region 42. For example, the low-speed etched region 44 may include, for example, B, BF, or a combination thereof, and the high-speed etched region 42 may include, for example P.

In some embodiments, the low-speed etched region 44 may include impurities at a lower dopant concentration than the high-speed etched region 42 and at a higher dopant concentration than the active region 23. The high-speed etched region 42 may include different impurities from the active region 23. The low-speed etched region 44 may include impurities at a higher dopant concentration than the active region 23. The low-speed etched region 44 may include different impurities from the active region 23. In some embodiments, one selected out of the high-speed etched region 42 and the low-speed etched region 44 may be omitted.

Referring to FIGS. 2 and 15, the high-speed etched region 42, the low-speed etched region 44, and the active region 23 may be etched to form a trench 55 adjacent to the preliminary gate electrode 33. The trenches 55 may be formed between the gate electrodes and the device isolation layer 29 and between adjacent gate electrodes 33 on the same active region 23. An isotropic etching process, a directional etching process, an anisotropic etching process, or a combination thereof, for example, may be applied to form the trench 55. The size, shape, and position of the trench 55 may be controlled as needed, according to configurations of the high-speed etched region 42 and the low-speed etched region 44. The trench 55 may be formed substantially uniformly in the entire surface of the substrate 21.

For example, the trench 55 may be formed by sequentially performing an isotropic etching process and a directional etching process. The isotropic etching process may be performed using, for example, HBr, CF₄, O₂, Cl₂, NF₃, or a combination thereof. During the isotropic etching process, the high-speed etched region 42 may be removed at a higher rate than the low-speed etched region 44. The directional etching process may include, for example, a wet etching process using, for example NH₄OH, NH₃OH, tetra methyl ammonium hydroxide (TMAH), KOH, NaOH, benzyltrimethylammonium hydroxide (BTMH), or a combination thereof.

The active region 23 and the device isolation layer 29 may be exposed within the trench 55. The trench 55 may include a first sidewall S1, a second sidewall S2, and a bottom S3 as described in connection with FIG. 1. The active region 23 may be exposed by the first sidewall S1, the second sidewall S2, and the bottom S3. The first sidewall S1 may be near the preliminary gate electrode 33 and relatively far away from the device isolation layer 29. The second sidewall S2 may be near the device isolation layer 29 and relatively far away from the preliminary gate electrode 33. The bottom S3 may couple the first sidewall S1 to the second sidewall S2.

The first sidewall S1 may be a sigma (Σ) shape or a notch shape. The first sidewall S1 may include a first upper sidewall S11 and a first lower sidewall S12. The first upper sidewall S11 may be in contact with the top surface of the active region 23. A crossing angle between the top surface of the active region 23 and the first upper sidewall S11 may form an acute angle. That is, the first upper sidewall S11 interfaces with the top surface of the active region 23 at an acute angle. The first lower sidewall S12 may be in contact with the first upper sidewall S11 and the bottom S3. A crossing angle between the bottom S3 and the first lower sidewall S12 may form an obtuse angle. That is, the first lower sidewall S12 interfaces with the bottom S3 at an obtuse angle. The first upper sidewall S11 and the first lower sidewall S12 may have a convergent interface.

The second sidewall S2 may be a step shape. The second sidewall S2 may include a second upper sidewall S21, a second middle sidewall S22, and a second lower sidewall S23. The second lower sidewall S23 may be spaced apart from the first lower sidewall S12 and may be in contact with the bottom S3. That is, the bottom S3 couples the first lower sidewall S12 to second lower sidewall S23. A crossing angle between the second lower sidewall S23 and the bottom S3 may form an obtuse angle. That is, the second lower sidewall S23 interfaces with the bottom S3 at an obtuse angle. The second middle sidewall S22 may be formed at a higher level than the bottom S3. The second middle sidewall S22 may be in contact with the second lower sidewall S23 and the second upper sidewall S21. A crossing angle between the second middle sidewall S22 and the second lower sidewall S23 may form an obtuse angle. That is, the second middle sidewall S22 interfaces with the second lower sidewall S23 at an obtuse angle.

The second middle sidewall S22 may be substantially parallel to the bottom S3. The second upper sidewall S21 may be spaced apart from the second lower sidewall S23 and may be in contact with the second middle sidewall S22. A crossing angle between the second upper sidewall S21 and the second middle sidewall S22 may form an obtuse angle. That is, the second upper sidewall S21 interfaces with the second middle sidewall S22 at an obtuse angle. One end of the second upper sidewall S21 may be in contact with the device isolation layer 29. The second upper sidewall S21 may be formed at a higher level than the second lower sidewall S23. The second upper sidewall S21 may be formed at a lower level than an upper end, or a top surface, of the device isolation layer 29.

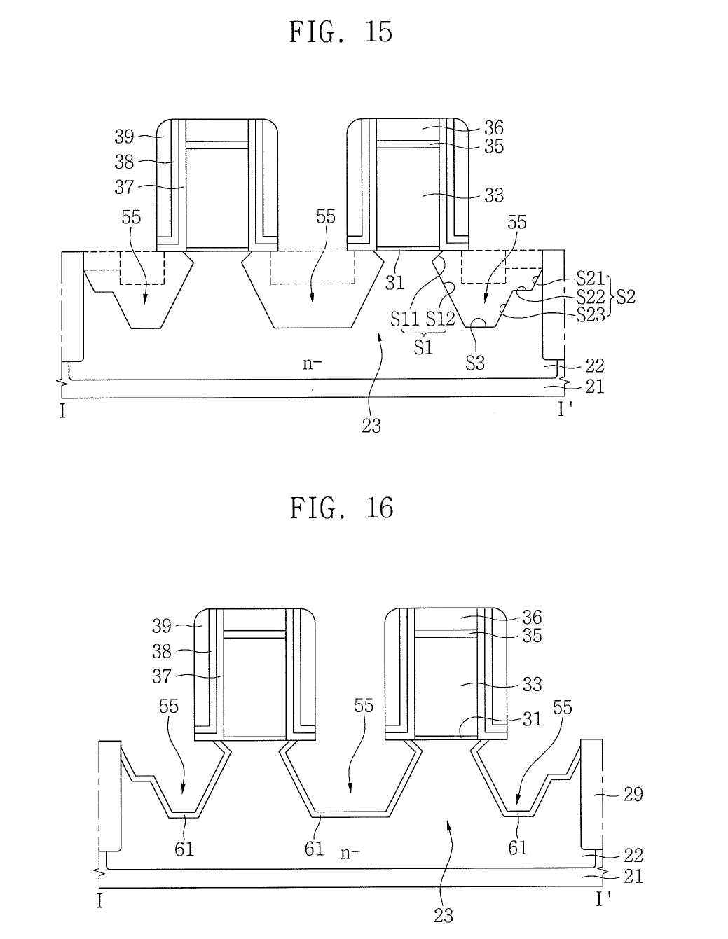

Referring to FIGS. 2 and 16, a first semiconductor layer 61 may be formed within the trench 55. The first semiconductor layer 61 may include, for example, undoped single-crystalline silicon germanium (SiGe) obtained using a selective epitaxial growth (SEG) method. Germanium may be contained in the first semiconductor layer 61 at a content of about 10 to 25%. The first semiconductor layer 61 may conformally cover an inner wall of the trench 55. The first semiconductor layer 61 may cover the first upper sidewall S11, the first lower sidewall S12, the bottom S3, the second lower sidewall S23, the second middle sidewall S22, and the second upper sidewall S21 in the trench 55.

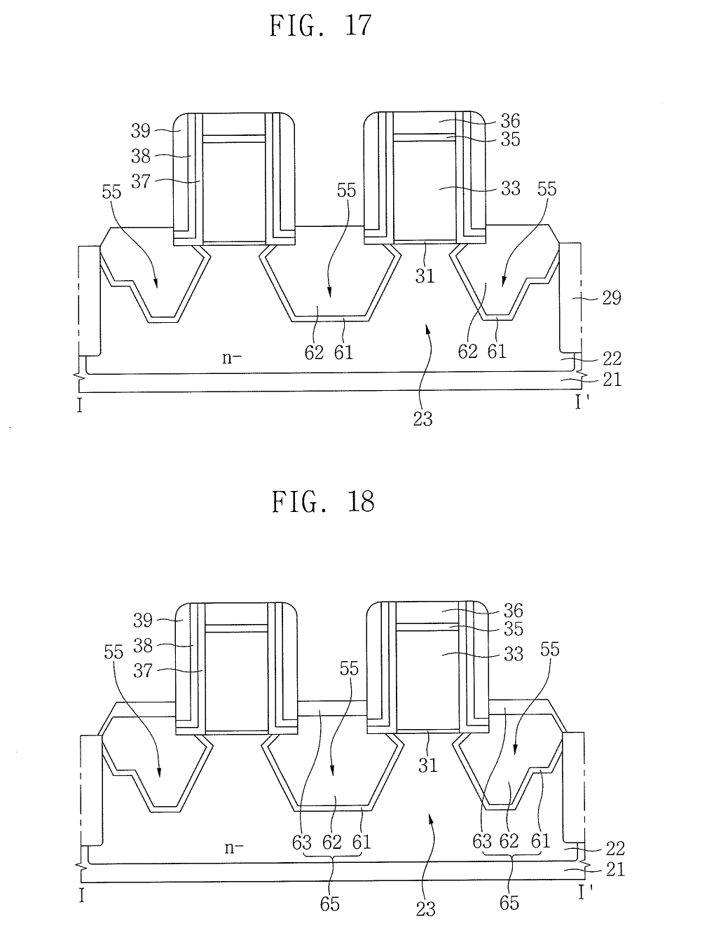

Referring to FIGS. 2 and 17, a second semiconductor layer 62 may be formed within the trench 55. The second semiconductor layer 62 may include, for example, boron-doped single-crystalline silicon germanium obtained using an SEG method. Germanium may be contained in the second semiconductor layer 62 at a higher content than in the first semiconductor layer 61. Germanium may be contained in the second semiconductor layer 62 at a content of about 25 to 50%. The second semiconductor layer 62 may contain boron at an atomic density of about 1E20 to 3E20 atoms/cm³. The second semiconductor layer 62 may completely fill the trench 55. An upper end, or top surface, of the second semiconductor layer 62 may protrude at a higher level than an upper end, or top surface, of the active region 23. The second semiconductor layer 62 may be in contact with side surfaces of the first spacers 37, the second spacers 38 and the third spacers 39.

Referring to FIGS. 2 and 18, a third semiconductor layer 63 may be formed on the second semiconductor layer 62. The third semiconductor layer 63 may include, for example, boron-doped single-crystalline silicon or boron-doped single-crystalline silicon germanium obtained using an SEG method. Germanium may be contained in the third semiconductor layer 63 at a lower content than in the second semiconductor layer 62. Germanium may be contained in the third semiconductor layer 63 at a content of about 10% or less. The third semiconductor layer 63 may contain boron at an atomic density of about 1E20 to 3E20 atoms/cm³. The first semiconductor layer 61, the second semiconductor layer 62 and the third semiconductor layer 63 may comprise an embedded stressor 65. The embedded stressor 65 may be referred to as a strain-inducing pattern. The third semiconductor layer 63 may be referred to as a capping layer.

In some embodiments, the first semiconductor layer 61 may be omitted.

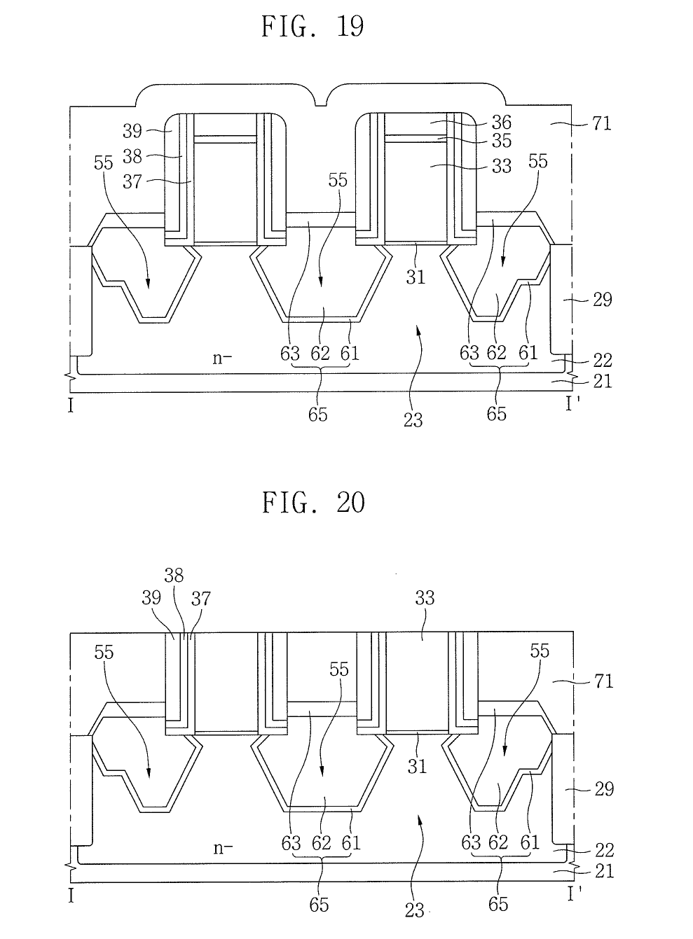

Referring to FIGS. 2 and 19, an interlayer insulating layer 71 may be formed on the substrate 21. The interlayer insulating layer 71 may include, for example an insulating material, for example, silicon oxide, silicon nitride, silicon oxynitride, or a combination thereof.

In some embodiments, before the interlayer insulating layer 71 is formed, some additional processes, such as a metal silicidation process and an annealing process, may be performed on the third semiconductor layer 63, but a description thereof is omitted.

Referring to FIGS. 2 and 20, the interlayer insulating layer 71 may be partially removed, and the second mask pattern 36 and the first mask pattern 35 may be removed to expose the preliminary gate electrode 33. The interlayer insulating layer 71, the second mask pattern 36 and the first mask pattern 35 may be removed using, for example, a chemical mechanical polishing (CMP) process, an etch-back process, or a combination thereof. The interlayer insulating layer 71 may remain on the third semiconductor layer 63 and the device isolation layer 29 after being partially removed.

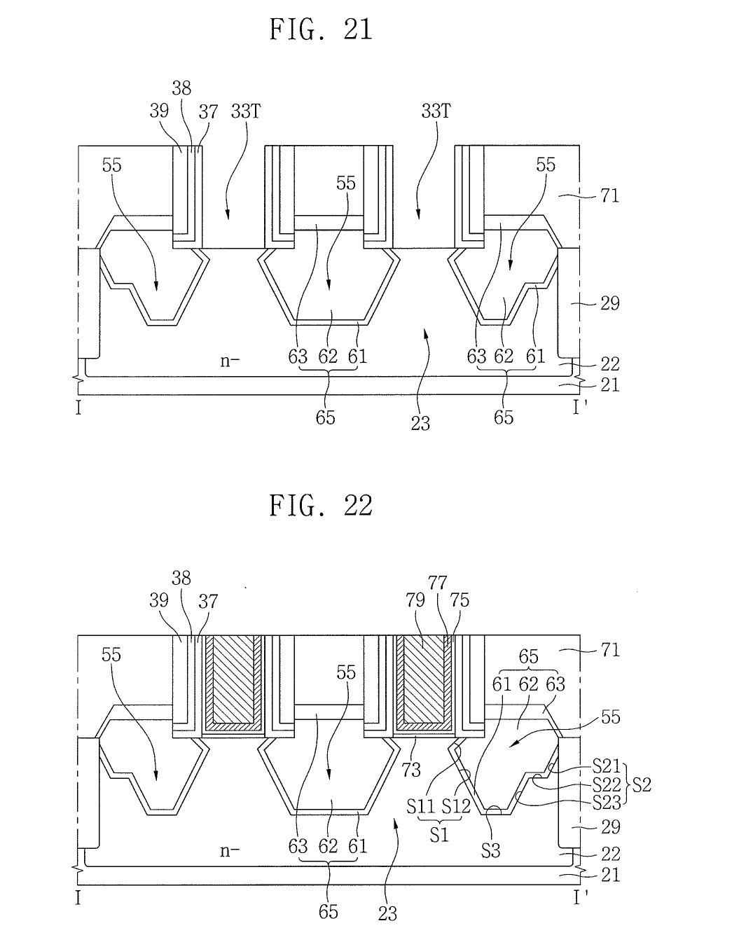

Referring to FIGS. 2 and 21, the preliminary gate electrode 33 and the preliminary gate dielectric layer 31 may be removed to form a gate trench 33T exposing the active region 23.

Referring to FIGS. 2 and 22, a first gate dielectric layer 73, a second gate dielectric layer 75, a lower gate electrode 77, and an upper gate electrode 79 may be formed within the gate trench 33T.

The first gate dielectric layer 73 may be formed on the active region 23. The first gate dielectric layer 73 may be referred to as, for example, an interfacial oxide layer. The first gate dielectric layer 73 may be formed using, for example, a cleaning process. The first gate dielectric layer 73 may include, for example, silicon oxide. The second gate dielectric layer 75 may include silicon oxide, silicon nitride, silicon oxynitride, a high-k dielectric material, or a combination thereof. For example, the second gate dielectric layer 75 may contain HfO or HfSiO. The second gate dielectric layer 75 may be formed on the first gate dielectric layer 73 and along sidewalls of the first spacer 37. The second gate dielectric layer 75 may surround side and bottom surfaces of the lower gate electrode 77. The first gate dielectric layer 73 may be interposed between the active region 23 and the second gate dielectric layer 75.

The lower gate electrode 77 may surround side and bottom surfaces of the upper gate electrode 79. The lower gate electrode 77 may be formed along inner sidewalls of the second gate dielectric layer 75. The lower gate electrode 77 may include, for example, a conductive layer in consideration of a work function. For example, the lower gate electrode 77 may include, for example, titanium nitride (TiN) or tantalum nitride (TaN). The upper gate electrode 79 may include, for example, a metal layer, such as a tungsten (W) layer.

In some embodiments, the lower gate electrode 77 may include, for example, titanium aluminum (TiAl) or titanium aluminum carbide (TiAlC).

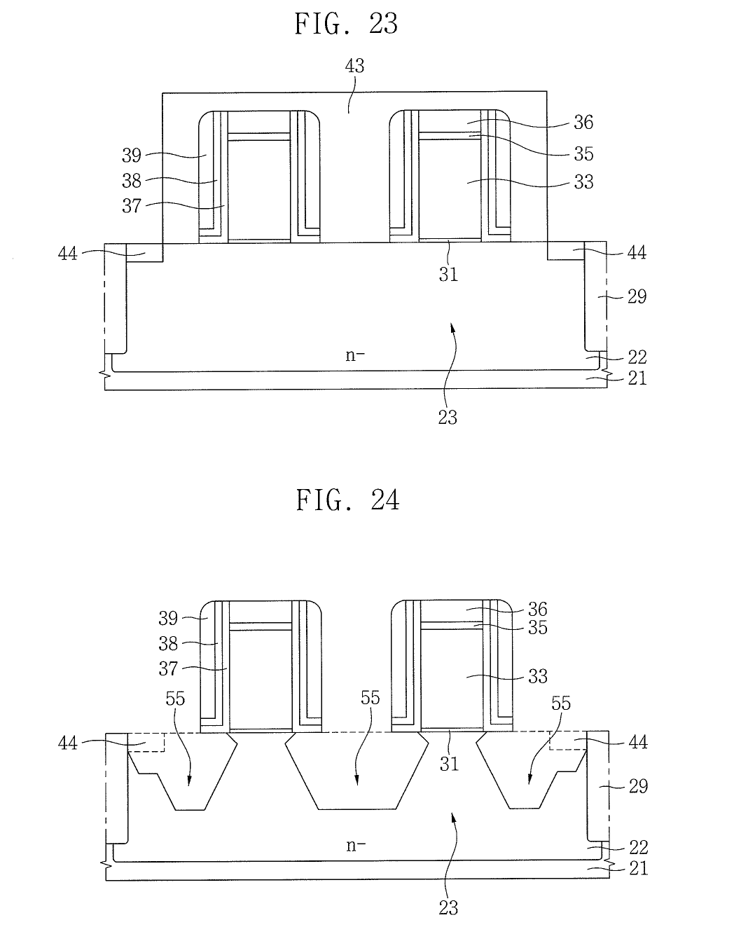

FIGS. 23 and 24 are cross-sectional views taken along line I-I′ of FIG. 2 illustrating a method of fabricating a semiconductor device according to example embodiments of the present inventive concepts.

Referring to FIGS. 2 and 23, a fourth mask pattern 43 may be formed on the substrate 21. A low-speed etched region 44 may be formed in the active region 23 using the fourth mask pattern 43 as an ion implantation mask. An ion implantation process for forming the low-speed etched region 44 may be performed using various energy levels and various doses. The fourth mask pattern 43 may be removed to expose the active region 23 and the low-speed etched region 44.

The fourth mask pattern 43 may partially cover the preliminary gate electrode 33 and the active region 23. The fourth mask pattern 43 may cover the active region 23, which may be near the preliminary gate electrode 33 and relatively far away from the device isolation layer 29. The fourth mask pattern 43 may partially cover a portion of the active region adjacent to the preliminary gate electrode 33 and expose a portion of the active region adjacent to the device isolation layer 29. The low-speed etched region 44 may be formed in the active region 23, which may be near the device isolation layer 29 and relatively far away from the preliminary gate electrode 33. The active region 23 may remain without the ion implantation therein between the preliminary gate electrode 33 and the low-speed etched region 44.

The low-speed etched region 44 may include, for example, B, BF, P, As, Ba, Ge, Si, Ga, Sn, Sb, C, N, or a combination thereof. The low-speed etched region 44 may contain different impurities from the active region 23.

Referring to FIGS. 2 and 24, the low-speed etched region 44 and the active region 23 may be etched to form a trench 55 adjacent to the preliminary gate electrode 33. An isotropic etching process, a directional etching process, an anisotropic etching process, or a combination thereof, for example, may be applied to form the trench 55. The size, shape, and position of the trench 55 may be controlled as needed, according to configurations of the active region 23 and the low-speed etched region 44. The trench 55 may be formed substantially uniformly in the entire surface of the substrate 21.

For example, the trench 55 may be formed by sequentially performing an isotropic etching process and a directional etching process. The isotropic etching process may be performed using, for example, HBr, CF₄, O₂, Cl₂, NF₃, or a combination thereof. During the isotropic etching process, the active region 23 may be removed at a higher rate than the low-speed etched region 44. The directional etching process may include a wet etching process using, for example, NH₄OH, NH₃OH, TMAH, KOH, NaOH, BTMH, or a combination thereof.

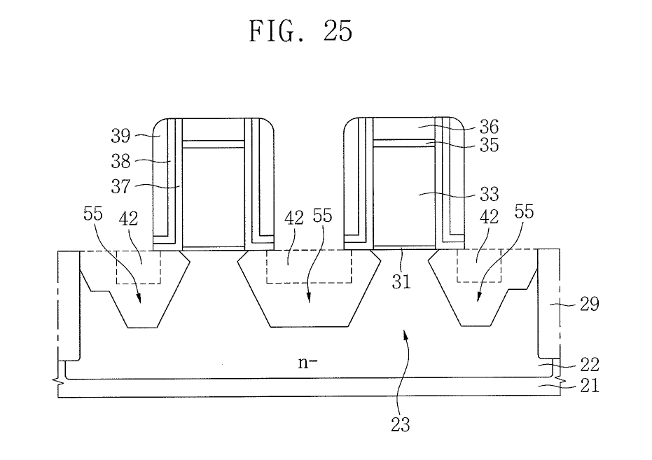

FIG. 25 is a cross-sectional view taken along line I-I′ of FIG. 2 illustrating a method of fabricating a semiconductor device according to example embodiments of the present inventive concepts.

Referring to FIGS. 2, 13, and 25, the high-speed etched region 42 may be formed in the active region 23. An ion implantation process for forming the high-speed etched region 42 may be performed using various energy levels and various doses. The low-speed etched region (refer to 44 in FIG. 14) may be omitted. The active region 23 may remain without the ions implanted therein between the high-speed etched region 42 and the device isolation layer 29.

The high-speed etched region 42 and the active region 23 may be etched to form a trench 55 adjacent to the preliminary gate electrode 33. An isotropic etching process, a directional etching process, an anisotropic etching process, or a combination thereof, for example, may be applied to form the trench 55. The size, shape, and position of the trench 55 may be controlled as needed, according to configurations of the active region 23 and the high-speed etched region 42. The trench 55 may be formed substantially uniformly in the entire surface of the substrate 21.

For example, the trench 55 may be formed by sequentially performing an isotropic etching process and a directional etching process. The isotropic etching process may be performed using, for example, HBr, CF₄, O₂, Cl₂, NF₃, or a combination thereof. During the isotropic etching process, the active region 23 may be removed at a lower rate than the high-speed etched region 42. The directional etching process may include, for example, a wet etching process using, for example, NH₄OH, NH₃OH, TMAH, KOH, NaOH, BTMH, or a combination thereof.

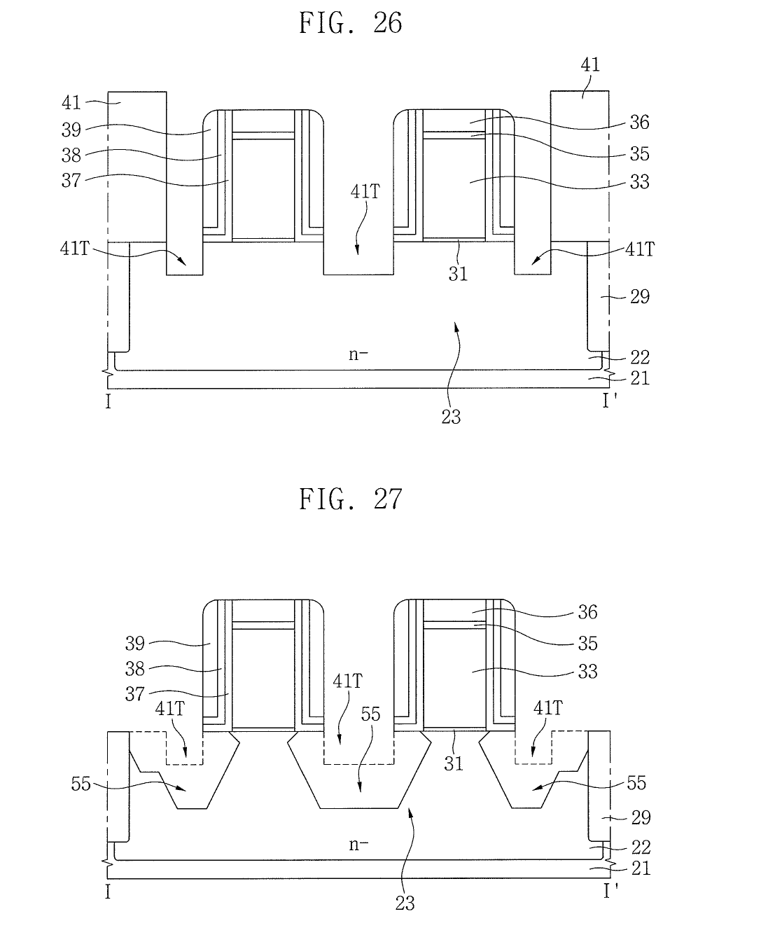

FIGS. 26 and 27 are cross-sectional views taken along line I-I′ of FIG. 2, illustrating a method of fabricating a semiconductor device according to embodiments of the inventive concept.

Referring to FIGS. 2 and 26, a third mask pattern 41 may be formed on the substrate 21. A preliminary trench 41T may be formed in the active region 23 using the third mask pattern 41, the second mask pattern 36, the first spacers 37, the second spacers 38, and the third spacers 39 as an etch mask. The formation of the preliminary trench 41T may be performed using, for example, an anisotropic etching process. The third mask pattern 41 may be removed to expose the preliminary trench 41T and the active region 23. The low-speed etched region (refer to 44 in FIG. 14) may be omitted. The active region 23 may be remain unetched between the preliminary trench 41T and the device isolation layer 29.

Referring to FIGS. 2 and 27, the preliminary trench 41T may be expanded to form a trench 55 adjacent to the preliminary gate electrode 33. An isotropic etching process, a directional etching process, an anisotropic etching process, or a combination thereof; for example, may be applied to form the trench 55. The size, shape, and position of the trench 55 may be controlled as needed, using a configuration of the preliminary trench 41T. The trench 55 may be formed substantially uniformly in the entire surface of the substrate 21.

For example, the trench 55 may be formed by sequentially performing an isotropic etching process and a directional etching process. The isotropic etching process may be performed using, for example, HBr, CF₄, O₂, Cl₂, NF₃, or a combination thereof. The directional etching process may include, for example, a wet etching process using, for example, NH₄OH, NH₃OH, TMAH, KOH, NaOH, BTMH, or a combination thereof.

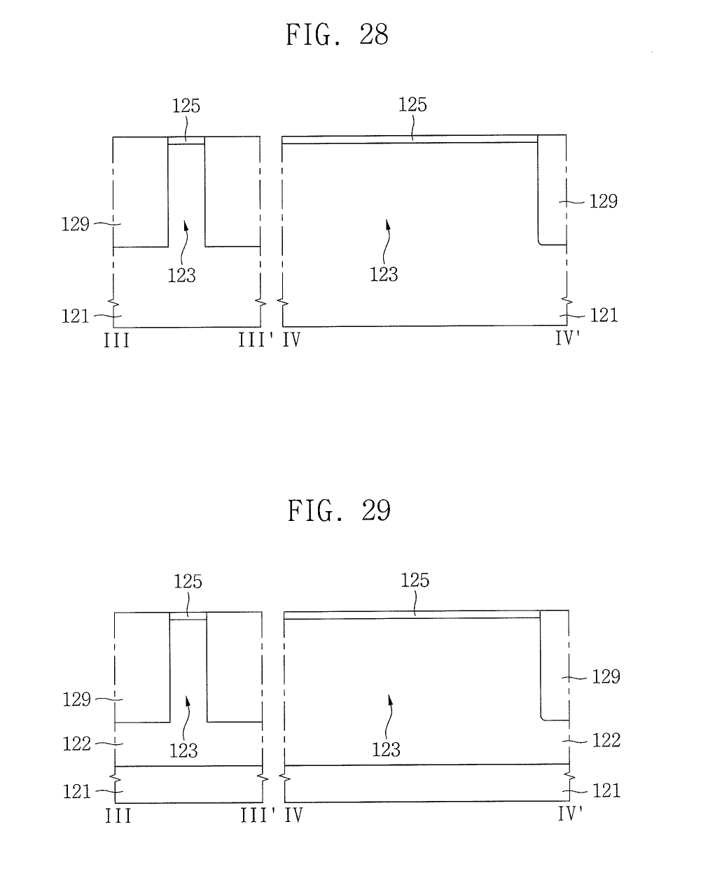

FIGS. 28 through 42 are cross-sectional views taken along lines and IV-IV′ of FIG. 7 illustrating a method of fabricating a semiconductor device according to example embodiments of the present inventive concepts.

Referring to FIGS. 7 and 28, a device isolation layer 129 may be formed on a substrate 121 to define an active region 123. A top surface of the active region 123 may be covered with a buffer layer 125.

The active region 123 may have various shapes, for example, a fin shape or a wire shape. For example, the active region 123 may include fin-shaped single-crystalline silicon having a relatively long major axis. The device isolation layer 129 may be formed using, for example, an STI technique. The device isolation layer 129 may include an insulating material, for example, silicon oxide, silicon nitride, silicon oxynitride, or a combination thereof. The buffer layer 125 may include, for example, an insulating material, such as silicon oxide, silicon nitride, silicon oxynitride, or a combination thereof.

Referring to FIGS. 7 and 29, an N-well 122 may be formed in a predetermined region of the substrate 121. The active region 123 may be defined on the N-well 122. Channel ions may be implanted into the active region 123. The active region 123 may contain impurities of the same conductivity type as the N-well 122. The N-well 122 may be formed by implanting impurities of a different conductivity type from the substrate 121. For example, the N-well 122 may be formed by implanting N-type impurities to a predetermined depth from the surface of the substrate 121. The substrate 121 may include, for example, boron (B), and the N-well 122 may include, for example, arsenic (As), phosphorus (P), or a combination thereof.

In some embodiments, the N-well 122 may be formed before the device isolation layer 129 is formed. In some embodiments, the N-well 122 may be omitted.

Referring to FIGS. 7 and 30, the device isolation layer 129 may be recessed to expose side surfaces of the active region 123. The device isolation layer 129 may remain at a lower level than the upper end of the active region 123. During the recessing of the device isolation layer 129, the buffer layer 125 may also be removed. The top surface of the active region 123 may be partially, removed. The device isolation layer 129 may be recessed using, for example, an etch-back process. Upper corners of the active region 123 may be formed to be rounded.

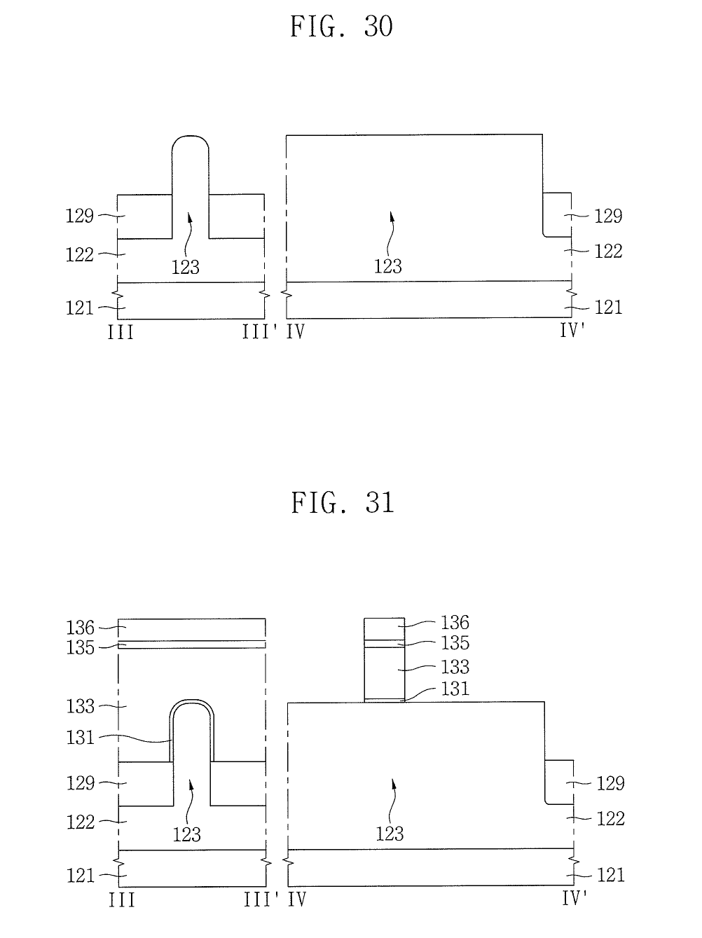

Referring to FIGS. 7 and 31, a preliminary gate dielectric layer 131, a preliminary gate electrode 133, a first mask pattern 135, and a second mask pattern 136 may be formed on the active region 123. The preliminary gate electrode 133 may be formed using, for example, a thin layer forming process, a CMP process, and a patterning process. The preliminary gate dielectric layer 131, the preliminary gate electrode 133, the first mask pattern 135, and the second mask pattern 136 may be referred to as a preliminary gate structure.

The preliminary gate electrode 133 may cross the active region 123. The preliminary gate electrode 133 may cover side and top surfaces of the active region 123. A lower end of the preliminary gate electrode 133 may be formed at a lower level than the upper end, or top surface, of the active region 123 and at a higher level than a bottom surface of the active region 123. The preliminary gate dielectric layer 131 may be formed between the active region 123 and the preliminary gate electrode 133. The preliminary gate dielectric layer 131 may include an insulating material, for example, silicon oxide, silicon nitride, silicon oxynitride, or a combination thereof. The preliminary gate electrode 133 may include, for example, poly-Si. The first mask pattern 135 may include, for example, silicon oxide. The second mask pattern 136 may include, for example, silicon nitride.

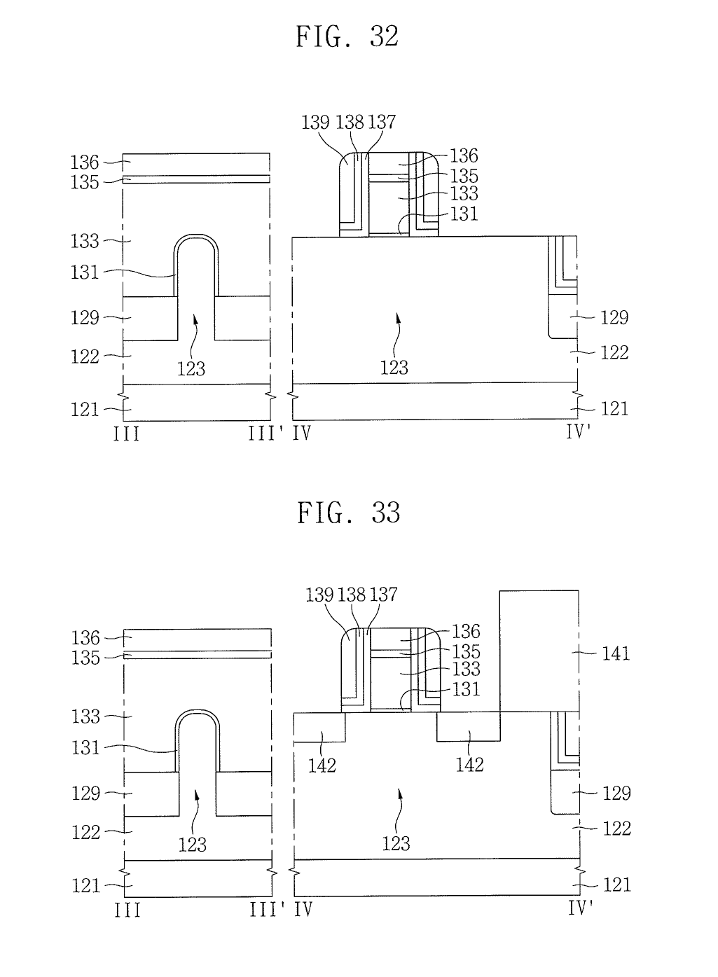

Referring to FIGS. 7 and 32, first spacers 137, second spacers 138, and third spacers 139 may be sequentially formed on side surfaces of the preliminary gate structures 131, 133, 135, and 136.

Referring to FIGS. 7 and 33, a third mask pattern 141 may be formed on the substrate 121. A high-speed etched region 142 may be formed in the active region 123 using the third mask pattern 141 as an ion implantation mask. The first spacers 37, the second spacers 38, the third spacers 39 and the second mask pattern 36 may be used as an ion implantation mask. An ion implantation process for forming the high-speed etched region 142 may be performed using various energy levels and various doses. The third mask pattern 141 may be removed to expose the high-speed etched region 142 and the active region 123. The high-speed etched region 142 may be formed in the active region 123 near the preliminary gate electrode 133. The active region 123 may remain without the ion implantation therein between the high-speed etched region 142 and the device isolation layer 129. That is, the third mask pattern 41 is formed on a portion of the active region 23 adjacent to the device isolation layer 29 and is spaced apart from the preliminary gate electrode 33.

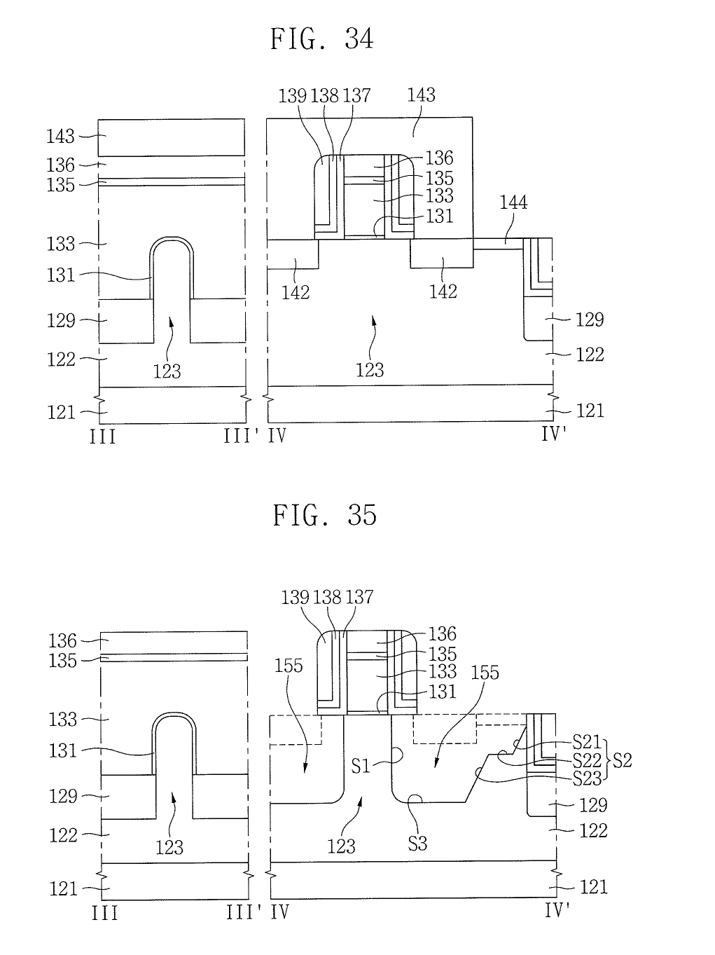

Referring to FIGS. 7 and 34, a fourth mask pattern 143 may be formed on the substrate 121. A low-speed etched region 144 may be formed in the active region 123 using the fourth mask pattern 143 as an ion implantation mask. An ion implantation process for forming the low-speed etched region 144 may be performed using various energy levels and various doses. A sidewall of the fourth mask pattern 43 may be substantially vertically aligned with an outer sidewall of the high-speed etched region 42. The fourth mask pattern 143 may be removed to expose the high-speed etched region 142 and the low-speed etched region 144.

The fourth mask pattern 143 may partially cover the preliminary gate electrode 133 and the active region 123. The fourth mask pattern 143 may cover the active region 123, which may be near the preliminary gate electrode 133 and relatively far away from the device isolation layer 129. The fourth mask pattern 143 may cover the high-speed etched region 142. The fourth mask pattern 43 may expose the portion of the active region 23 between the high-speed etched region 42 and the device isolation layer 29. The low-speed etched region 144 may be formed in the active region 123, which may be near the device isolation layer 129 and relatively far away from the preliminary gate electrode 133. The low-speed etched region 144 may be formed in the active region 123 between the high-speed etched region 142 and the device isolation layer 129.

A lower end of the high-speed etched region 142 may be formed at a lower level than a lower end of the low-speed etched region 144. A lower end of the low-speed etched region 144 may be formed at a higher level than the lower end of the high-speed etched region 142. First side surfaces of the low-speed etched region 144 may be in contact with a side surface of the high-speed etched region 142 and a second side surface of the low-speed etched region 144 may be in contact with the first spacer 137 over the device isolation layer 129. Top surfaces of the active region 123, the high-speed etched region 142, and the low-speed etched region 144 may be substantially coplanar. The lower end of the high-speed etched region 142 may be formed at a higher level than a lower end of the device isolation layer 129.

The high-speed etched region 142 and the low-speed etched region 144 may include, for example, B, BF, P, As, Ba, Ge, Si, Ga, Sn, Sb, C, N, or a combination thereof. The high-speed etched region 142 may include impurities at a higher dopant concentration than the active region 123. The low-speed etched region 144 may include impurities at a lower dopant concentration than the high-speed etched region 142.

The low-speed etched region 144 may include different impurities from the high-speed etched region 142. For example, the low-speed etched region 144 may include, for example, B, BF, or a combination thereof, and the high-speed etched region 142 may include, for example, P.

In some embodiments, the low-speed etched region 144 may include impurities at a lower dopant concentration than the high-speed etched region 142 and at a higher dopant concentration than the active region 123. The high-speed etched region 142 may include different impurities from the active region 123. The low-speed etched region 144 may include impurities at a higher dopant concentration than the active region 123. The low-speed etched region 144 may include different impurities from the active region 123. In some embodiments, one selected out of the high-speed etched region 142 and the low-speed etched region 144 may be omitted.

Referring to FIGS. 7 and 35, the high-speed etched region 142, the low-speed etched region 144, and the active region 123 may be etched to form a trench 155 adjacent to the preliminary gate electrode 133. The trenches 55 may be formed between the gate electrodes and the device isolation layer 29 and between adjacent gate electrodes 33 on the same active region 23. An isotropic etching process, a directional etching process, an anisotropic etching process, or a combination thereof, for example, may be applied to form the trench 155. The size, shape, and position of the trench 155 may be controlled as needed, using configurations of the high-speed etched region 142 and the low-speed etched region 144. The trench 155 may be formed substantially uniformly in the entire surface of the substrate 121.

For example, the trench 155 may be formed by sequentially performing an isotropic etching process and a directional etching process. The isotropic etching process may be performed using, for example, HBr, CF₄, O₂, Cl₂, NF₃, or a combination thereof. During the isotropic etching process, the high-speed etched region 142 may be removed at a higher rate than the low-speed etched region 144. The directional etching process may include a wet etching process using, for example, NH₄OH, NH₃OH, TMAH, KOH, NaOH, BTMH, or a combination thereof.

The trench 155 may include a first sidewall S1, a second sidewall S2, and a bottom S3. The active region 123 may be exposed by the first sidewall S1, the second sidewall S2, and the bottom S3. The first sidewall S1 may be near the preliminary gate electrode 133 and relatively far away from the device isolation layer 129. The second sidewall S2 may be near the device isolation layer 129 and relatively far away from the preliminary gate electrode 133. The bottom S3 may couple the first sidewall S1 to the second sidewall S2.

The first sidewall S1 may be vertically formed with respect to the surface of the substrate 121. The first sidewall S1 may extend substantially vertical to the bottom S3 of the trench 155. The first sidewall S1, the second sidewall S2 and the bottom S3 are formed along sidewalls of the active region 123. The second sidewall S2 may have a step shape. The second sidewall S2 may include a second upper sidewall S21, a second middle sidewall S22, and a second lower sidewall S23. The second lower sidewall S23 may be spaced apart from the first sidewall S1 and may be in contact with the bottom S3. The bottom S3 may couple the first sidewall S1 and the second sidewall S2. A crossing angle between the second lower sidewall S23 and the bottom S3 may form an obtuse angle. That is, the second lower sidewall S23 interfaces with the bottom S3 at an obtuse angle. The second middle sidewall S22 may be formed at a higher level than the bottom S3. The second middle sidewall S22 may be in contact with the second lower sidewall S23 and the second upper sidewall S21. A crossing angle between the second middle sidewall S22 and the second lower sidewall S23 may form an obtuse angle. That is, the second middle sidewall S22 interfaces with the second lower sidewall S23 at an obtuse angle.

The second middle sidewall S22 may be substantially parallel to the bottom S3. The second upper sidewall S21 may be spaced apart from the second lower sidewall S23 and may be in contact with the second middle sidewall S22. A crossing angle between the second upper sidewall S21 and the second middle sidewall S22 may form an obtuse angle. That is, the second upper sidewall S21 interfaces with the second middle sidewall S22 at an obtuse angle. The second upper sidewall S21 may be formed at a higher level than the second lower sidewall S23.

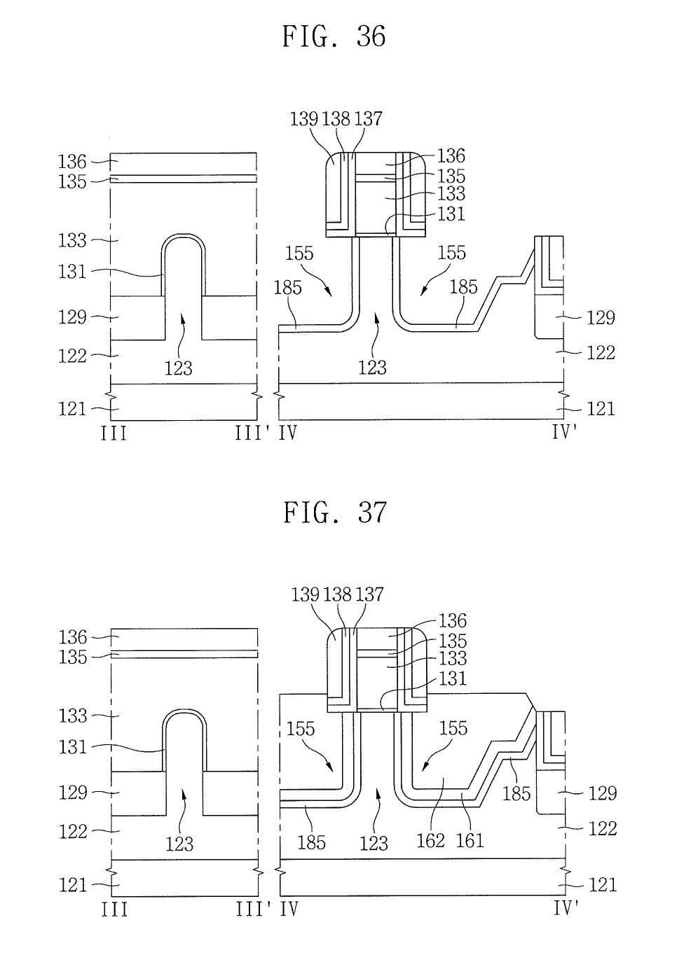

Referring to FIGS. 7 and 36, an LDD 185 may be formed using, for example, an ion implantation process in the active region 123 exposed within the trench 155. For example, the active region 123 may include arsenic (As) or phosphorus (P), and the LDD 185 may be formed by, for example, implanting boron (B) into the active region 123. The LDD 185 may be formed to a substantially uniform thickness on inner walls of the trench 155.

In some embodiments, the LDD 185 may be omitted.

Referring to FIGS. 7 and 37, a first semiconductor layer 161 and a second semiconductor layer 162 may be sequentially formed within the trench 155. The first semiconductor layer 161 may include, for example, undoped single-crystalline silicon germanium obtained using, for example, an SEG method. Germanium may be contained in the first semiconductor layer 161 at a content of about 10 to 25%. The first semiconductor layer 161 may conformally cover the inner walls of the trench 155.

The second semiconductor layer 162 may include, for example, boron-doped single-crystalline silicon germanium obtained using an SEG method. Germanium may be contained in the second semiconductor layer 162 at a higher content than in the first semiconductor layer 161. Germanium may be contained in the second semiconductor layer 162 at a content of about 25 to 50%. The second semiconductor layer 162 may contain boron at an atomic density of about 1E20 to 3E20 atoms/cm³. The second semiconductor layer 162 may completely fill the trench 155. An upper end, or top surface, of the second semiconductor layer 162 may protrude at a higher level than the active region 123. The second semiconductor layer 162 may be in contact with side surfaces of the first spacers 137, the second spacers 138 and the third spacers 139.

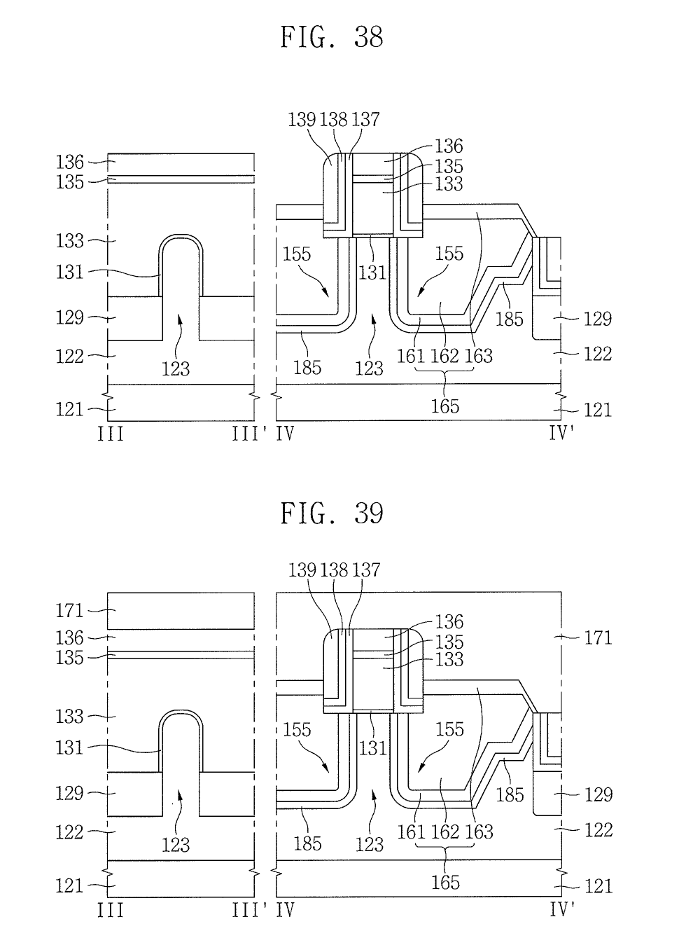

Referring to FIGS. 7 and 38, a third semiconductor layer 163 may be formed on the second semiconductor layer 162. The third semiconductor layer 163 may include, for example, boron-doped single-crystalline silicon or boron-doped single-crystalline silicon germanium obtained using an SEG method. Germanium may be contained in the third semiconductor layer 163 at a lower content than in the second semiconductor layer 162. Germanium may be contained in the third semiconductor layer 163 at a content of 10% or less. The third semiconductor layer 163 may contain, for example, boron at an atomic density of about 1E20 to 3E20 atoms/cm³. The first semiconductor layer 161, the second semiconductor layer 162, and the third semiconductor layer 163 may comprise an embedded stressor 165. The embedded stressor 165 may be referred to as a strain-inducing pattern. The third semiconductor layer 163 may be referred to as a capping layer.

In some embodiments, the first semiconductor layer 161 may be omitted.

Referring to FIGS. 7 and 39, an interlayer insulating layer 171 may be formed on the substrate 121. The interlayer insulating layer 171 may include, for example, an insulating material, for example, silicon oxide, silicon nitride, silicon oxynitride, or a combination thereof.

In some embodiments, before the interlayer insulating layer 171 is formed, some additional processes, such as a metal silicidation process and an annealing process, may be performed on the third semiconductor layer 163.

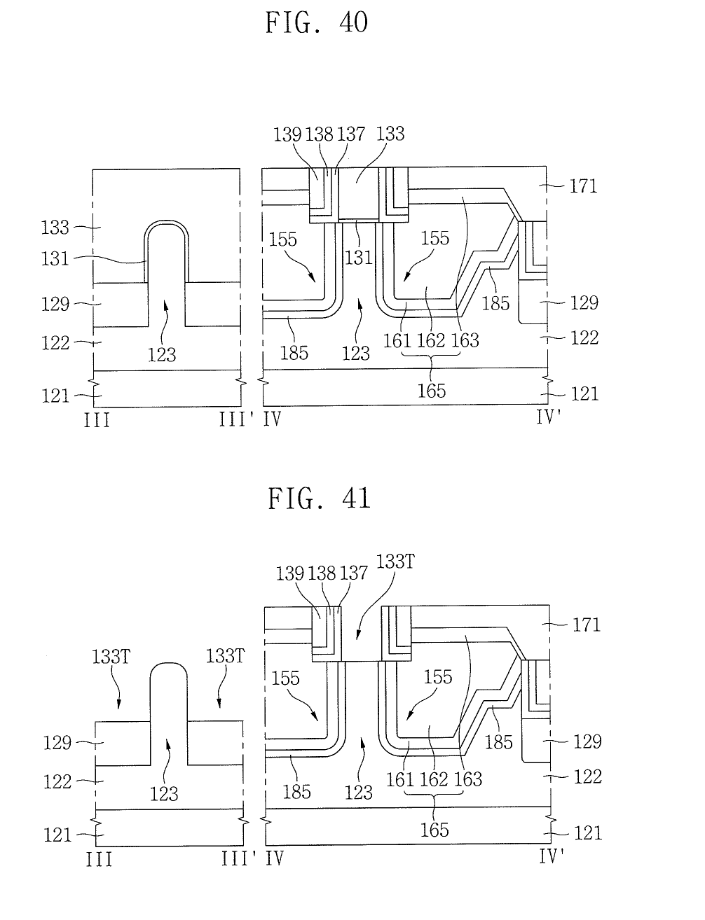

Referring to FIGS. 7 and 40, the interlayer insulating layer 171 may be partially removed, and the second mask pattern 136 and the first mask pattern 135 may be removed to expose the preliminary gate electrode 133. The interlayer insulating layer 171, the second mask pattern 136 and the first mask pattern 135 may be removed using, for example, a CMP process, an etchback process, or a combination thereof. The interlayer insulating layer 171 may remain on the third semiconductor layer 163 and the device isolation layer 129 after being partially removed.

Referring to FIGS. 7 and 41, the preliminary gate electrode 133 and the preliminary gate dielectric layer 131 may be removed to form a gate trench 133T exposing the active region 123.

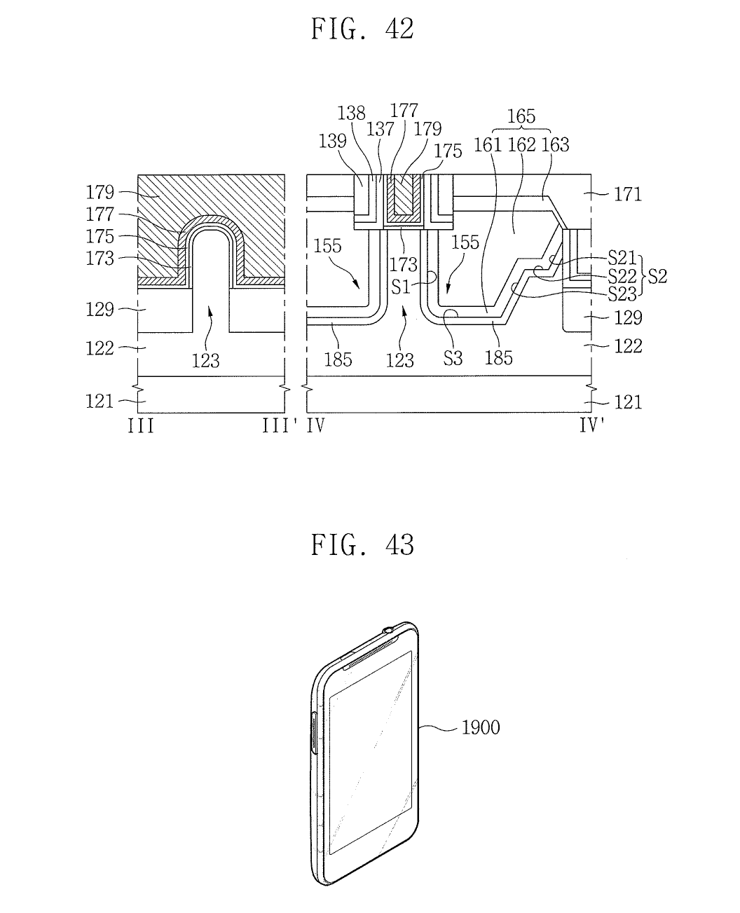

Referring to FIGS. 7 and 42, a first gate dielectric layer 173, a second gate dielectric layer 175, a lower gate electrode 177, and an upper gate electrode 179 may be formed within the gate trench 133T.

The first gate dielectric layer 173 may be formed on the active region 123. The first gate dielectric layer 173 may be referred to as, for example, an interfacial oxide layer. The first gate dielectric layer 173 may be formed using, for example, a cleaning process. The first gate dielectric layer 173 may include, for example, silicon oxide. The second gate dielectric layer 175 may include, for example, silicon oxide, silicon nitride, silicon oxynitride, a high-k dielectric material, or a combination thereof. The second gate dielectric layer 175 may be formed on the first gate dielectric layer 173 and along sidewalls of the first spacer 137. The second gate dielectric layer 175 may surround side and bottom surfaces of the lower gate electrode 177. The first gate dielectric layer 173 may be interposed between the active region 123 and the second gate dielectric layer 175.

The lower gate electrode 177 may surround side and bottom surfaces of the upper gate electrode 179. The lower gate electrode 177 may be formed along inner sidewalls of the second gate dielectric layer 175. The lower gate electrode 177 may include, for example, a conductive layer in consideration of a work function. For example, the lower gate electrode 177 may include, for example, TiN or TaN. The upper gate electrode 179 may include, for example, a metal layer, such as a W layer. The upper gate electrode 179 may cover top and side surfaces of the active region 123. A lower end of the upper gate electrode 179 may be formed at a lower level than a top surface of the active region 123.

In some embodiments, the lower gate electrode 177 may include, for example, TiAl or TiAlC.

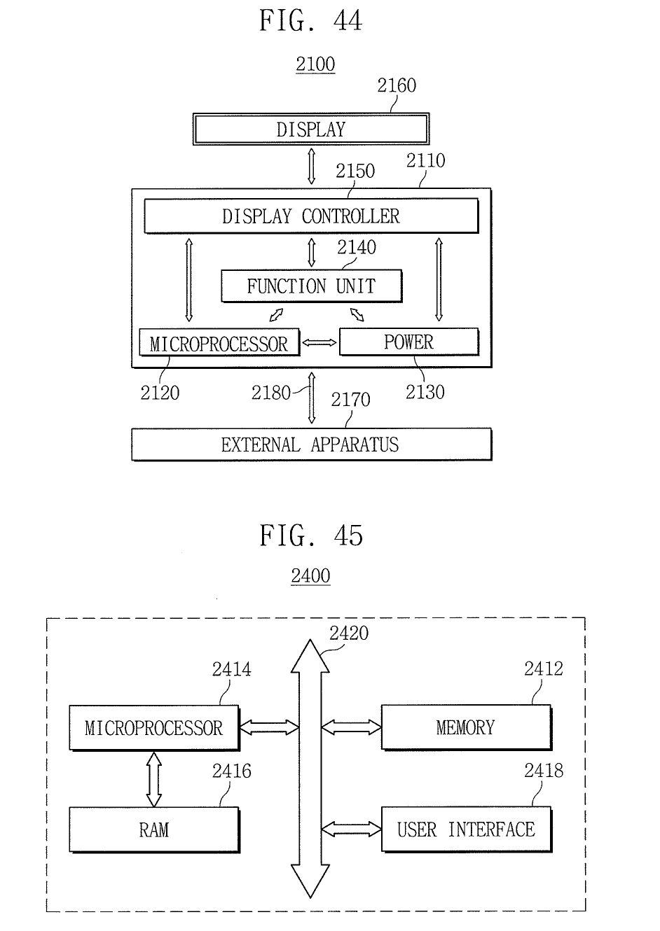

FIGS. 43 and 44 are a perspective view and a system block diagram, respectively, of an electronic device according to example embodiments of the present inventive concepts.

Referring to FIG. 43, a semiconductor device similar to those described with reference to FIGS. 1 through 42 may be applied to electronic systems, for example, a smart phone 1900, a netbook, a laptop computer, a tablet personal computer (PC) or the like. For example, the semiconductor device similar to those described with reference to FIGS. 1 through 42 may be mounted on a mainboard included in the smart phone 1900. Furthermore, the semiconductor device similar to those described with reference to FIGS. 1 through 42 may be provided to an expansion device, such as an external memory card, and used in combination with the smart phone 1900.

Referring to FIG. 44, a semiconductor device similar to those described with reference to FIGS. 1 through 42 may be applied to an electronic system 2100. The electronic system 2100 may include a body 2110, a microprocessor (MP) 2120, a power unit 2130, a function unit 2140, and/or a display controller 2150. The body 2110 may be a motherboard having a printed circuit board (PCB). The MP 2120, the power unit 2130, the function unit 2140, and the display controller 2150 may be mounted on the body 2110. In some embodiments, the display 2160 may be disposed inside the body 2110. In some embodiments, the display 2160 may be disposed outside the body 2110. For example, the display 2160 may be disposed on a surface of the body 2110 and display an image processed by the display controller 2150.

The power unit 2130 may receive a predetermined voltage from an external battery, divide the predetermined voltage into various voltage levels, and transmit the divided voltages to the MP 2120, the function unit 2140, and the display controller 2150. The MP 2120 may receive a voltage from the power unit 2130 and control the function unit 2140 and the display 2160. The function unit 2140 may implement various functions of the electronic system 2100. For instance, when the electronic system 2100 is a smart phone, the function unit 2140 may include several elements capable of portable phone functions, for example, output of an image to the display 2160 or output of a voice to a speaker, by dialing or communication with an external apparatus 2170. When the function unit 2140 includes a camera, the function unit 2140 may serve as an image processor.

In some embodiments, when the electronic system 2100 is connected to a memory card to increase capacity, the function unit 2140 may be a memory card controller. The function unit 2140 may exchange signals with the external apparatus 2170 through a wired or wireless communication unit 2180. In addition, when the electronic system 2100 requires a universal serial bus (USB) to expand functions thereof, the function unit 2140 may serve as an interface controller. Furthermore, the function unit 2140 may include a mass storage.

The semiconductor device similar to those described with reference to FIGS. 1 through 42 may be provided in the function unit 2140 or the MP 2120. For example, the MP 2120 may include the embedded stressor 65.

FIG. 45 is a schematic block diagram of an electronic system 2400 including at least one of the semiconductor devices according to example embodiments of the present inventive concepts.

Referring to FIG. 45, the electronic system 2400 may include at least one of the semiconductor devices according to various example embodiments of the present inventive concepts. The electronic system 2400 may be used to fabricate, for example, a mobile device or a computer. For example, the electronic system 2400 may include a memory system 2412, a microprocessor (MP) 2414, a random access memory (RAM) 2416, a bus 2420, and a user interface 2418. The MP 2414, the memory system 2412, and the user interface 2418 may be connected to one another via the bus 2420. The user interface 2418 may be used to input data to the electronic system 2400 and/or output data from the electronic system 2400. The MP 2414 may program and control the electronic system 2400. The RAM 2416 may be used as an operational memory of the MP 2414. The MP 2414, the RAM 2416, and/or other elements may be assembled within a single package. The memory system 2412 may store codes for operating the MP 2414, data processed by the MP 2414, or external input data. The memory system 2412 may include a controller and a memory.

The semiconductor device similar to those described with reference to FIGS. 1 through 42 may be provided in the MP 2414, the RAM 2416, or the memory system 2412. For instance, the MP 2414 may include the embedded stressor 65.

According to example embodiments of the present inventive concepts, a trench having first and second sidewalls is formed in an active region adjacent to a gate electrode. A stressor is formed within the trench. A second sidewall of the trench is near a device isolation layer and relatively far away from the gate electrode. The second sidewall of the trench has a step shape. The shape of the stressor may be controlled due to a configuration of the second sidewall. The stressor may densely fill the inside of the trench. The semiconductor device of the present inventive concepts is advantageous in that it has increased integration density and has good electrical properties.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of the present inventive concepts as defined in the claims.

What is claimed is:

1. A semiconductor device comprising:
a device isolation layer configured to define an active region on a substrate;
a gate electrode on the active region;
a trench formed in the active region adjacent to the gate electrode, the trench having first and second sidewalls; and
a stressor within the trench,
wherein the first sidewall of the trench is nearer to the gate electrode than to the device isolation layer,
wherein the second sidewall of the trench is nearer the device isolation layer than to the gate electrode, and
wherein the second sidewall of the trench has a step shape.

2. The device of claim 1, wherein the second sidewall of the trench includes an upper sidewall, a middle sidewall, and a lower sidewall,
wherein the middle sidewall is inclined at a different slope than the upper sidewall and the lower sidewall,
wherein the upper sidewall is formed at a higher level than the lower sidewall, and
wherein the middle sidewall is formed between the upper sidewall and the lower sidewall.

3. The device of claim 2, wherein the middle sidewall is substantially parallel to a bottom of the trench.

4. The device of claim 2, wherein the middle sidewall is formed at a higher level than a lower end of the stressor.

5. The device of claim 2, wherein a crossing angle between the bottom of the trench and the lower sidewall is an obtuse angle,
wherein a crossing angle between the lower sidewall and the middle sidewall is an obtuse angle, and
wherein a crossing angle between the middle sidewall and the upper sidewall is an obtuse angle.

6. The device of claim 2, wherein the upper sidewall is formed at a lower level than an upper end of the device isolation layer.

7. The device of claim 2, wherein the upper sidewall is formed at a lower level than an upper end of the active region.

8. The device of claim 1, wherein the first sidewall of the trench has a sigma (E) shape or a notch shape.

9. The device of claim 1, wherein the first sidewall of the trench includes:
an upper sidewall being in contact with a top surface of the active region; and
a lower sidewall formed between a bottom of the trench and the upper sidewall,
wherein the upper sidewall and the lower sidewall have a convergent interface.

10. The device of claim 9, wherein a crossing angle between the top surface of the active region and the upper sidewall is an acute angle, and
a crossing angle between the bottom of the trench and the lower sidewall is an obtuse angle.

11. The device of claim 1, wherein the stressor comprises:
a first semiconductor layer;
a second semiconductor layer on the first semiconductor layer; and
a third semiconductor layer on the second semiconductor layer,
wherein the first semiconductor layer and the second semiconductor layer include silicon germanium (SiGe), and
wherein germanium (Ge) is contained in the second semiconductor layer at a higher content than in the first semiconductor layer.

12. The device of claim 11, wherein the third semiconductor layer contains silicon (Si) or silicon germanium, and
wherein germanium is contained in the third semiconductor layer at a lower content than in the second semiconductor layer.

13. A semiconductor device comprising:
a device isolation layer configured to define an active region on a substrate;
a gate electrode covering at least one side surface of the active region;
a trench formed in the active region adjacent to the gate electrode, the trench having first and second sidewalls; and
a stressor within the trench,
wherein the first sidewall of the trench is nearer to the gate electrode than to the device isolation layer,
wherein the second sidewall of the trench is nearer to the device isolation layer than the gate electrode, and
wherein the second sidewall of the trench has a step shape.

14. The device of claim 13, wherein a lower end of the gate electrode is formed at a lower level than an upper end of the active region.

15. The device of claim 13, wherein the second sidewall of the trench includes an upper sidewall, a middle sidewall, and a lower sidewall, and
wherein the middle sidewall is inclined at a different slope from the upper sidewall and the lower sidewall.

16. A semiconductor device comprising:
a device isolation layer configured to define an active region on a substrate;
a gate electrode on the active region;
a trench formed in the active region adjacent to the gate electrode, the trench comprising:
a first sidewall near the gate electrode;
a second sidewall contacting the device isolation layer and having a step shape; and
a bottom, wherein the first sidewall is spaced apart from the second sidewall by the bottom; and
a stressor within the trench.

17. The device of claim 16, wherein the second sidewall of the trench includes an upper sidewall, a middle sidewall, and a lower sidewall,
wherein the middle sidewall is inclined at a different slope than the upper sidewall and the lower sidewall,
wherein the upper sidewall is formed at a higher level than the lower sidewall, and
wherein the middle sidewall is formed between the upper sidewall and the lower sidewall.

18. The device of claim 17, wherein the middle sidewall is substantially parallel to a bottom of the trench.

19. The device of claim 17, wherein a crossing angle between the bottom of the trench and the lower sidewall is an obtuse angle,
wherein a crossing angle between the lower sidewall and the middle sidewall is an obtuse angle, and
wherein a crossing angle between the middle sidewall and the upper sidewall is an obtuse angle.

20. The device of claim 16, wherein the stressor comprises:
a first semiconductor layer;
a second semiconductor layer on the first semiconductor layer; and
a third semiconductor layer on the second semiconductor layer,
wherein the first semiconductor layer and the second semiconductor layer include silicon germanium (SiGe), and
wherein germanium (Ge) is contained in the second semiconductor layer at a higher content than in the first semiconductor layer.
